(19) United States
(12) Patent Application Publication
(10) Pub. No.: US 2025/0286346 A1
(43) Pub. Date: Sep. 11, 2025

(54) TECHNOLOGIES FOR TUNABLE LASERS IN PHOTONIC INTEGRATED CIRCUIT DIES

(71) Applicant: Intel Corporation, Santa Clara, CA (US)

(72) Inventors: Jacob S. Levy, Sierra Madre, CA (US); Amit Mizrahi, San Jose, CA (US); Sergei Sochava, Sunnyvale, CA (US)

(73) Assignee: Intel Corporation, Santa Clara, CA (US)

(21) Appl. No.: 19/075,318

(22) Filed: Mar. 10, 2025

Related U.S. Application Data
(60) Provisional application No. 63/563,858, filed on Mar. 11, 2024.

(51) Int. Cl. H01S 5/06; H01S 5/062; H01S 5/40

(52) U.S. Cl. CPC H01S 5/0612; H01S 5/062; H01S 5/4025

(57) ABSTRACT

Technologies for tunable lasers in a photonic integrated circuit (PIC) die are disclosed. In an illustrative embodiment, a system includes one or more PIC dies with several lasers and a temperature control device such as a thermoelectric device. Control circuitry can control the temperature control device to tune an average frequency of the lasers on the PIC die, and the control circuitry can control laser driver current to further tune the frequency of individual lasers of the PIC die. The control circuitry can align the lasers of the PIC die to channels on a grid for a communication protocol. Light from the lasers can be modulated within the channels to communicate information.

### CROSS-REFERENCE TO RELATED APPLICATIONS

This application claims the benefit of priority under 35 U.S.C. § 119 (e) U.S. provisional patent application No. 63/563,858, filed Mar. 11, 2024, and entitled “TECHNOLOGIES FOR TUNABLE LASERS IN PHOTONIC INTEGRATED CIRCUIT DIES.” The disclosure of the prior application is considered part of and is hereby incorporated by reference in its entirety in the disclosure of this application.

### BACKGROUND

Photonic integrated circuits (PICs) can be used for several applications, such as optical communication. Some optical communication systems operate at multiple channels separated by a fixed amount. Lasers on PIC dies may vary slightly in frequency, so lasers on a PIC die may not line up with channels in a communication protocol.

### BRIEF DESCRIPTION OF THE DRAWINGS

FIG. 1 is an isometric view of one embodiment of a photonic integrated circuit (PIC) die with multiple lasers.

FIG. 2 is a diagram showing frequencies for the lasers of FIG. 1 compared to nominal channel frequencies.

FIG. 3 is a diagram showing frequencies for the lasers of FIG. 1 compared to nominal channel frequencies after adjusting an average frequency of the lasers of FIG. 1.

FIG. 4 is a diagram showing frequencies for the lasers of FIG. 1 compared to nominal channel frequencies after adjusting the frequency of each of the lasers of FIG. 1.

FIG. 5 is a diagram showing current for the lasers of FIG. 1 compared to a nominal current.

FIG. 6 is a diagram showing current for the lasers of FIG. 1 compared to a nominal current after adjusting the current of each of the lasers of FIG. 1.

FIG. 7 is a plot showing minimum and maximum power of the laser grid array of FIG. 1 as a function of average current.

FIG. 8 is a diagram showing frequency for the lasers of FIG. 1 and currents for the lasers of FIG. 1 in one embodiment.

FIG. 9 is a diagram showing frequency for the lasers of FIG. 1 and currents for the lasers of FIG. 1 in one embodiment.

FIG. 10 is a diagram showing frequency for the lasers of FIG. 1 and currents for the lasers of FIG. 1 in one embodiment.

FIG. 11 is a simplified block diagram of one embodiment of the system of FIG. 1.

FIG. 12 is one embodiment of a flow chart for a method of operating the laser array of FIG. 1.

FIG. 13 is one embodiment of a flow chart for a method of operating the laser array of FIG. 1.

FIG. 14 is one embodiment of a flow chart for a method of operating the laser array of FIG. 1.

FIG. 15 is a diagram of one embodiment of multiple PIC dies on a thermo-electric cooler.

FIG. 16 is a top view of a wafer and dies that may be included in a microelectronic assembly, in accordance with any of the embodiments disclosed herein.

FIG. 17 is a cross-sectional side view of an integrated circuit device that may be included in a microelectronic assembly, in accordance with any of the embodiments disclosed herein.

FIGS. 18A-18D are perspective views of example planar, gate-all-around, and stacked gate-all-around transistors.

FIG. 19 is a cross-sectional side view of an integrated circuit device assembly that may include a microelectronic assembly, in accordance with any of the embodiments disclosed herein.

FIG. 20 is a block diagram of an example electrical device that may include a microelectronic assembly, in accordance with any of the embodiments disclosed herein.

### DETAILED DESCRIPTION

In various embodiments disclosed herein, a system includes one or more photonic integrated circuit (PIC) dies that include several lasers and a temperature control device that is thermally coupled to the PIC dies. Control circuitry can control the temperature control device to control an average temperature of the one or more PIC dies and the lasers on the one or more PIC dies. Control circuitry can also control a current of individual lasers on the one or more PIC dies. The control circuitry can use the temperature and current controls to control a frequency of each of the lasers to align the lasers with a frequency grid for a communication protocol.

As used herein, the phrase “communicatively coupled” refers to the ability of a component to send a signal to or receive a signal from another component. The signal can be any type of signal, such as an input signal, an output signal, or a power signal. A component can send or receive a signal to another component to which it is communicatively coupled via a wired or wireless communication medium (e.g., conductive traces, conductive contacts, air). Examples of components that are communicatively coupled include integrated circuit dies located in the same package that communicate via an embedded bridge in a package substrate and an integrated circuit component attached to a printed circuit board that send signals to or receives signals from other integrated circuit components or electronic devices attached to the printed circuit board.

In the following description, specific details are set forth, but embodiments of the technologies described herein may be practiced without these specific details. Well-known circuits, structures, and techniques have not been shown in detail to avoid obscuring an understanding of this description. Phrases such as “an embodiment,” “various embodiments,” “some embodiments,” and the like may include features, structures, or characteristics, but not every embodiment necessarily includes the particular features, structures, or characteristics.

Some embodiments may have some, all, or none of the features described for other embodiments. “First,” “second,” “third,” and the like describe a common object and indicate different instances of like objects being referred to. Such adjectives do not imply objects so described must be in a given sequence, either temporally or spatially, in ranking, or any other manner. “Connected” may indicate elements are in direct physical or electrical contact, and “coupled” may indicate elements co-operate or interact, but they may or may not be in direct physical or electrical contact. Furthermore, the terms “comprising,” “including,” “having,” and the like, as used with respect to embodiments of the present disclosure, are synonymous. Terms modified by the word “substantially” include arrangements, orientations, spacings, or positions that vary slightly from the meaning of the unmodified term. For example, the central axis of a magnetic plug that is substantially coaxially aligned with a through hole may be misaligned from a central axis of the through hole by several degrees. In another example, a substrate assembly feature, such as a through width, that is described as having substantially a listed dimension can vary within a few percent of the listed dimension.

It will be understood that in the examples shown and described further below, the figures may not be drawn to scale and may not include all possible layers and/or circuit components. In addition, it will be understood that although certain figures illustrate transistor designs with source/drain regions, electrodes, etc. having orthogonal (e.g., perpendicular) boundaries, embodiments herein may implement such boundaries in a substantially orthogonal manner (e.g., within +/−5 or 10 degrees of orthogonality) due to fabrication methods used to create such devices or for other reasons.

The disclosed embodiments may be implemented, in some cases, in hardware, firmware, software, or any combination thereof. The disclosed embodiments may also be implemented as instructions carried by or stored on a transitory or non-transitory machine readable (e.g., computer-readable) storage medium, which may be read and executed by one or more processors. A machine-readable storage medium may be embodied as any storage device, mechanism, or other physical structure for storing or transmitting information in a form readable by a machine (e.g., a volatile or non-volatile memory, a media disc, or other media device).

Reference is now made to the drawings, which are not necessarily drawn to scale, wherein similar or same numbers may be used to designate the same or similar parts in different figures. The use of similar or same numbers in different figures does not mean all figures including similar or same numbers constitute a single or same embodiment. Like numerals having different letter suffixes may represent different instances of similar components. The drawings illustrate generally, by way of example, but not by way of limitation, various embodiments discussed in the present document.

In the following description, for purposes of explanation, numerous specific details are set forth in order to provide a thorough understanding thereof. It may be evident, however, that the novel embodiments can be practiced without these specific details. In other instances, well-known structures and devices are shown in block diagram form in order to facilitate a description thereof. The intention is to cover all modifications, equivalents, and alternatives within the scope of the claims.

As used herein, the phrase “located on” in the context of a first layer or component located on a second layer or component refers to the first layer or component being directly physically attached to the second part or component (no layers or components between the first and second layers or components) or physically attached to the second layer or component with one or more intervening layers or components.

As used herein, the term “adjacent” refers to layers or components that are in physical contact with each other. That is, there is no layer or component between the stated adjacent layers or components. For example, a layer X that is adjacent to a layer Y refers to a layer that is in physical contact with layer Y.

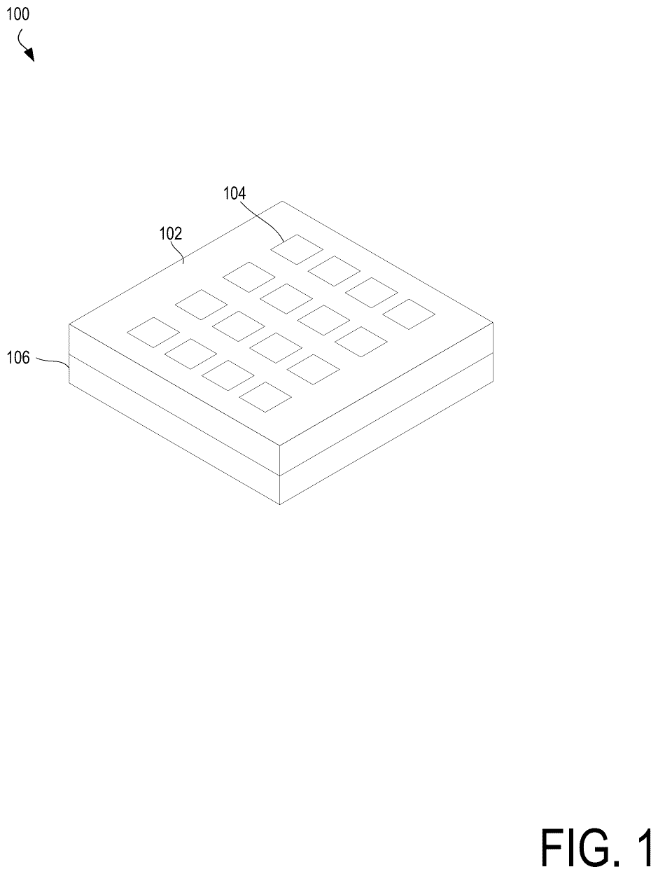

Referring now to FIG. 1, in one embodiment, a system 100 includes one or more photonic integrated circuit (PIC) dies 102. The one or more PIC dies 102 includes lasers 104, such as a grid of 2-64 lasers 104. A temperature control device 106 is thermally coupled to the PIC dies 102. The lasers 104 may be coupled to one or more additional optical components, such as filters, multiplexers, waveguides, free-space optics, optical fiber, etc. In some embodiments, lasers 104 of different wavelengths may be combined into one spatial mode, such as by using add/drop multiplexers.

In use, control circuitry can control the laser drive current for each laser 104 and control an amount of thermal power transferred between the PIC dies 102 and the temperature control device 106. The control circuitry may be embodied as any suitable combination of hardware, software, firmware, etc. For example, the control circuitry may form part of the one or more PIC die 102, may be part of an electrical integrated circuit near the one or more PIC dies, may be embodied as a processor and/or memory coupled to the one or more PIC dies, etc.

The PIC die 102 may be made of any suitable material, such as silicon. In an illustrative embodiment, waveguides for the lasers 104 may be silicon waveguides embedded in silicon oxide cladding. In some embodiments, the PIC die 102 may include other materials, such as silicon nitride waveguides, a III-V semiconductor material, silicon or other semiconductors doped with silicon, etc. The PIC die 102 may include, e.g., gallium, arsenic, indium, phosphorous, germanium, erbium, etc. Other optical components, such as optical fibers and/or optical interposers, may be connected to the PIC die 102 to provide optical signals into and out of the waveguides of the PIC die 102. In addition to the lasers 104, the PIC die 102 may include active or passive optical elements such as splitters, couplers, filters, optical amplifiers, lasers, photodetectors, modulators, etc. The PIC die 102 may include additional components, such as traces of copper or other conductors connected to active components, such as the lasers 104. The PIC die 102 may have any suitable length or width, such as 1-300 millimeters. The PIC die 102 may have any suitable thickness, such as 0.05-5 millimeters.

The lasers 104 may be any suitable type of laser, such as a distributed feedback laser, a vertical cavity surface emitting laser, a semiconductor laser, etc. The lasers 104 may operate in any suitable band, such as an O-band (about 1260-1360 nanometers) or C-band (about 1530-1565 nanometers). The lasers 104 may have any suitable power level, such as 0-20 dBm. The frequency of the lasers 104 may be shifted due to temperature shifts from the temperature control device 106 and/or from a change in the laser driver current by, e.g., 25-100 gigahertz.

In an illustrative embodiment, the lasers 104 are indium phosphide-based lasers. Each laser 104 may be on a separate indium phosphide die that is mounted on the PIC die 102. Additionally or alternatively, in some embodiments, the lasers 104 may be embodied as integrated silicon photonics lasers that are integrated into the PIC die 102. In some embodiments, the lasers 104 may be embodied usings hybrid integration of III/V semiconductors into silicon photonics.

The temperature control device 106 may be any suitable temperature control device, such as a thermoelectric device, a Peltier device, a resistive heater, and/or the like. The temperature control device 106 may be able to provide or remove any suitable amount of thermal power to or from the one or more PIC dies 102, such as 0-500 Watts.

In an illustrative embodiment, the system 100 includes sensors to determine various parameters for each of the lasers 104, such as the power, the frequency, the temperature, etc. The sensors may be included as part of the die with the lasers 104, on the PIC die 102, or as part of another component.

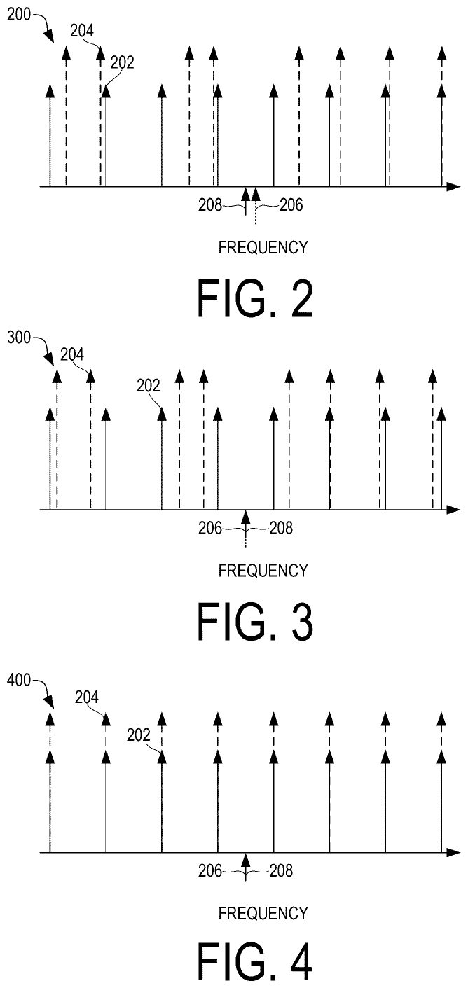

Referring now to FIGS. 2-5, graphs show various parameters of the system 100 in various embodiments at different stages of one frequency tuning methodology. In FIG. 2, a diagram 200 shows the frequencies 204 of the lasers 104 in one embodiment of the system 100 when operated at a nominal operating current and without active temperature control. The frequencies 204 of the lasers 104 can be compared to frequencies 202 corresponding to channels that form a grid of channels in a communication protocol. As a result of, e.g., process variations, cross-talk, ambient temperature shifts, etc., the frequencies 204 of the lasers 104 do not align with the frequencies 202 of the nominal frequency grid. The average frequency 208 of the lasers 104 does not line up with the average frequency 206 of the channel frequencies 202.

Referring now to FIG. 3, in one embodiment, control circuitry controls the temperature control device 106 to shift the frequencies of all of the lasers 104. A diagram 300 shows the frequencies 204 of the lasers 104 with active temperature control, with the average frequency 208 of the lasers 104 lining up with the average frequency 206 of the channels.

Referring now to FIG. 4, in one embodiment, after the temperature control device 106 is used to shift the average frequency of the lasers 104 to the average frequency 206 of the channels, the control circuitry controls the drive current of the individual lasers 104 to tune the frequency of each laser 104 to the frequency 202 of the nominal frequency grid, as shown in the plot 400.

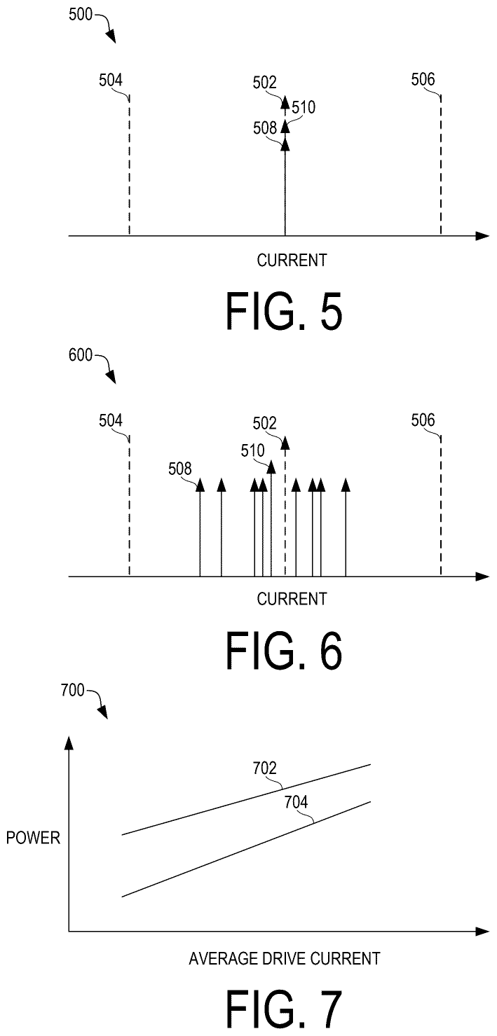

Referring now to FIG. 5, in one embodiment, the initial drive current 508 for each laser 104 is shown in a diagram 500, along with a nominal drive current 502, the average drive current 510, a minimum drive current 504, and a maximum drive current 506. For example, the minimum driver current 504 may be, e.g., 50-100 milliamps, and the maximum driver current may be, e.g., 100-200 milliamps, and the window between the minimum driver current 504 and the maximum driver current 506 may be, e.g., 10-100 milliamps. The diagram 500 corresponds to the laser frequencies 204 shown in, e.g., FIG. 3.

Referring now to FIG. 6, in one embodiment, a diagram 600 shows laser drive currents 508 for each laser 104 when the control circuitry controls the laser drive current to tune the frequency of the lasers 104. The diagram 600 corresponds to the laser frequencies 204 shown in, e.g., FIG. 4. The control circuitry may control the frequency of each laser 104 to be within, e.g., less than 5-20 gigahertz of the target frequency.

With the lasers 104 aligned to the channel frequencies, the light from the lasers can be modulated using, e.g., phase, frequency, and/or quadrature amplitude modulation to carry data to another device or another part of the system 100. Each channel may have an analog bandwidth of, e.g., 10-400 gigahertz, be spaced apart by, e.g., 10-500 gigahertz, and may carry a digital bandwidth of, e.g., 1-3,200 gigabits per second.

It should be appreciated that other tuning methodologies may be employed as well. For example, in one embodiment, the control circuitry may first set the temperature of the PIC dies 102 using the temperature control device 106 to shift the average frequency 208 of the lasers 104 to match the average frequency 206 of the channels. The control circuitry may then tune the current of the lasers 104 in order to align the individual channels to the grid. The control circuitry may then move the currents together in one direction or the other as much as possible, e.g., to set a power level close to the minimum current 504 or the maximum current 506 for each laser 104. The control circuitry may then adjust the temperature of the one or more PIC dies 102 using the temperature control device 106 to shift the average frequency 208 of the lasers 104 to match the average frequency 206 of the channels. The control circuitry can then fine-tune the current of the lasers 104 in order to align to the grid of channel frequencies. It should be appreciated that such an approach may allow for, e.g., operating the lasers 104 at a lower power, which may prolong the lifetime of the lasers 104 or may allow for, e.g., operating the lasers 104 at a higher power, which may increase a signal to noise ratio, potentially increasing communication bandwidth.

In another methodology, the control circuitry may determine and use knowledge of power vs. current for each laser while maximizing a minimum power and/or minimizing a maximum power. For example, in one embodiment, the control circuitry may modify the temperature of the one or more PIC dies 102 to shift the average frequency 208 to match the average channel frequency 206. The control circuitry may then tune the laser drive current for each laser 104 to align to the channel frequencies 202. The control circuitry can calculate an average current I_{C} and ΔIᵢ for the various channels using formulas

$${I}_{C} = \frac{1}{N} \sum {I}_{i}$$

and ΔIᵢ=I_{C}−Iᵢ, where N is the number of channels and Iᵢ is the current for channel i. The control circuitry can then map out parameters for the group of lasers 104 such as Pₘᵢₙ, Pₘₐₓ, difference between Pₘᵢₙ, Pₘₐₓ, etc., as a function of I_{C}. The control circuitry can then use the mapping of the parameters to control operation of the lasers 104 for different target operating conditions while maintaining alignment with the communication protocol frequency grid.

Referring now to FIG. 7, in one embodiment, a parametric plot 700 for an array of lasers 104 is shown. The plot 700 shows the maximum power 702 and minimum power 704 for any laser 104 in the array at a given average current I_{C}. At a specified average current, such as the average current 510 shown in FIG. 6, the different lasers 104 have different drive currents to align the lasers 104 to the desired grid of frequencies. As such, each lasers 104 has a different power, and one of the lasers 104 has the least power (e.g., the laser 104 with the lowest drive current), and one of the lasers 104 has the greatest power (e.g., the laser 104 with the highest drive current). If the thermal power provided or removed by the temperature control device 106 changes, the frequencies of individual lasers 104 and the average frequency will change to compensate, as will the maximum and minimum laser power of the lasers 104 in the array. The parametric plot 700 represents how the maximum and minimum laser power of the lasers 104 in the array change as the temperature and average laser driving current changes. It should be appreciated that the optical power will also depend on the backside temperature set by the temperature control device 106. When the current moves along the direction of the x-axis, the backside temperature is changed by the temperature control device 106 to maintain alignment with the prescribed frequency grid.

The plot 700 and similar plots may be constructed based on direct measurements on the lasers 104 and/or be constructed based on models constructed for the array of lasers 104 based on measurements of various aspects of the system 100.

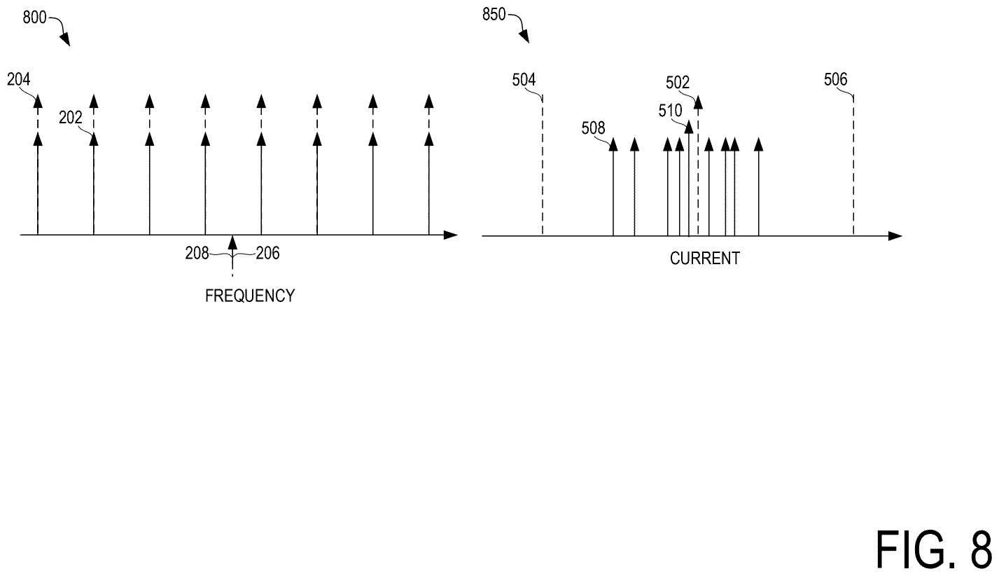

The information shown in the plot 700 can be used to tune the window of the minimum laser power and maximum laser power to a desired range. For example, a higher power range may be desired to achieve a higher signal-to-noise ratio, while a lower power range may be desired to achieve a lower power usage. FIGS. 8-10 show one possible embodiment for implementing such a shift. As shown in FIG. 8, in an initial state, the plot 800 shows the frequencies 204 of the lasers 104 aligned with the frequencies 202 of the nominal frequency grid. The plot 850 shows the drive current 508 of individual lasers 104.

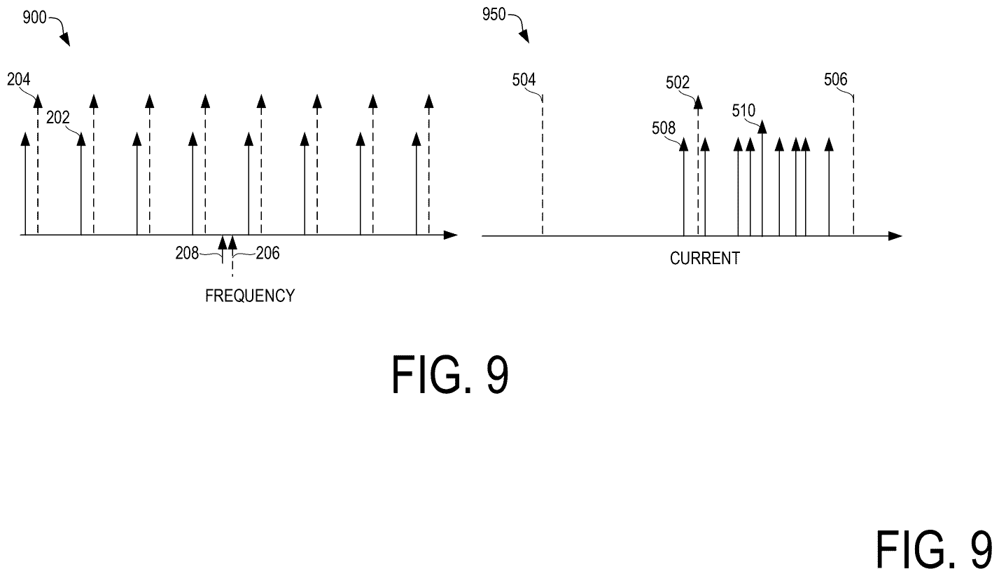

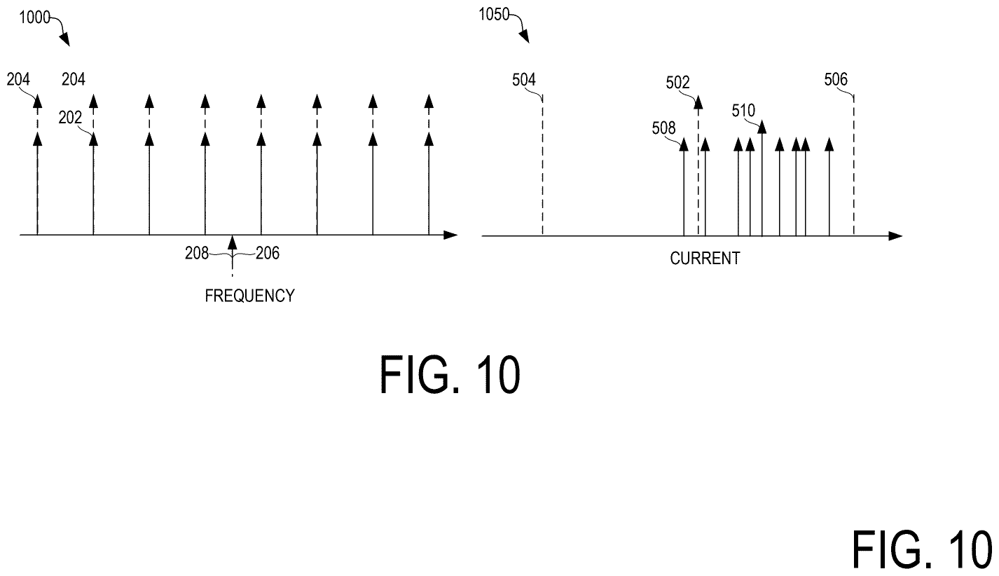

In order to increase the average power, the control circuitry may then increase the drive current 508 to each of the lasers 104, as shown in the plot 950 in FIG. 9. The increased drive current lowers the frequencies 202 of the individual lasers, as shown in the plot 900. In order to compensate, the control circuitry reduces the thermal power from the temperature control device 106 (e.g., by increasing the amount of cooling power). The frequencies 202 of the lasers then increases back to the nominal frequencies 204, as shown in the plot 1000 in FIG. 10. The average drive current 510, and therefore the average power, remains high, as shown in the plot 1050.

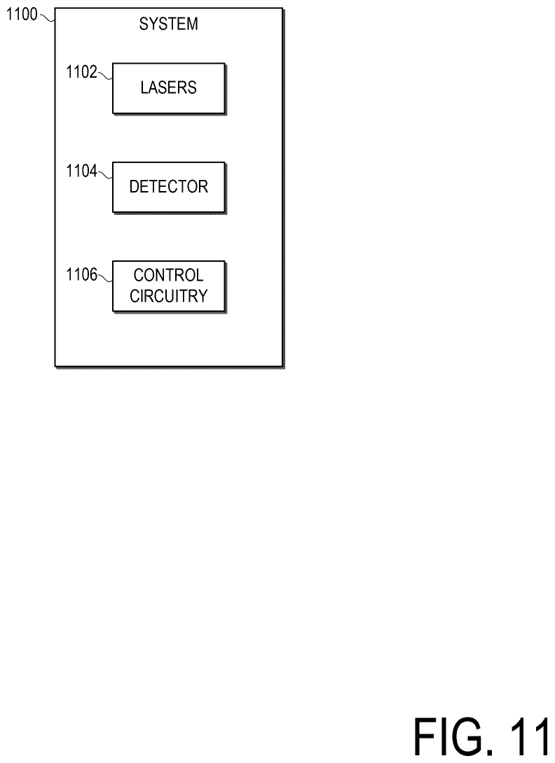

Referring now to FIG. 11, in one embodiment, a system 1100 includes lasers 1102, one or more detectors 1104, and control circuitry 1106. Some of the modules of the system 1100, such as the control circuitry 1106, may be embodied as hardware, software, firmware, or a combination thereof. For example, the various modules, logic, and other components of the system 1100 may form a portion of, or otherwise be established by, a processor, memory, data storage, or other hardware components of a computing device, such as the electrical device 2000 described below. The system 1100 may be embodied as a system-on-a-chip or a system-on-a-package. Such a system or package may include one or more electronic integrated circuit (EIC) dies and/or one or more PIC dies, such as any suitable embodiment of the PIC dies 102 described above. For example, in one embodiment, the lasers 1102 and the detector 1104 may be packaged together in one package or may be embodied in one PIC die 102. The control circuitry 1106 may be embodied as one or more EIC dies communicatively coupled to and/or packaged with the one or more PIC dies embodying the laser 1102 and the detector 1104. In one embodiment, the lasers 1102 may be embodied as one or more of the lasers 104. In some embodiments, the detectors 1104 may include a frequency locking system, a frequency discriminator, or some other frequency sensitive device that can provide information on the error in frequency.

In some embodiments, one or more of the modules of the system 1100 may be embodied as circuitry or collection of electrical devices (e.g., laser circuitry, detector circuitry, control circuitry 1106, etc.). It should be appreciated that, in such embodiments, one or more of the circuits (e.g., the laser circuitry, the detector circuitry, the control circuitry 1106, etc.) may form a portion of one or more of the processor, the memory, the data storage and/or other components of a computing device. For example, in some embodiments, some or all of the modules may be embodied as or include a processor as well as memory and/or data storage storing instructions to be executed by the processor. Additionally, in some embodiments, one or more of the illustrative modules may form a portion of another module and/or one or more of the illustrative modules may be independent of one another. Further, in some embodiments, one or more of the modules of the system 1100 may be embodied as virtualized hardware components or emulated architecture, which may be established and maintained by the processor or other components of a computing device. It should be appreciated that some of the functionality of one or more of the modules of the system 1100 may require a hardware implementation, in which case embodiments of modules that implement such functionality will be embodied at least partially as hardware.

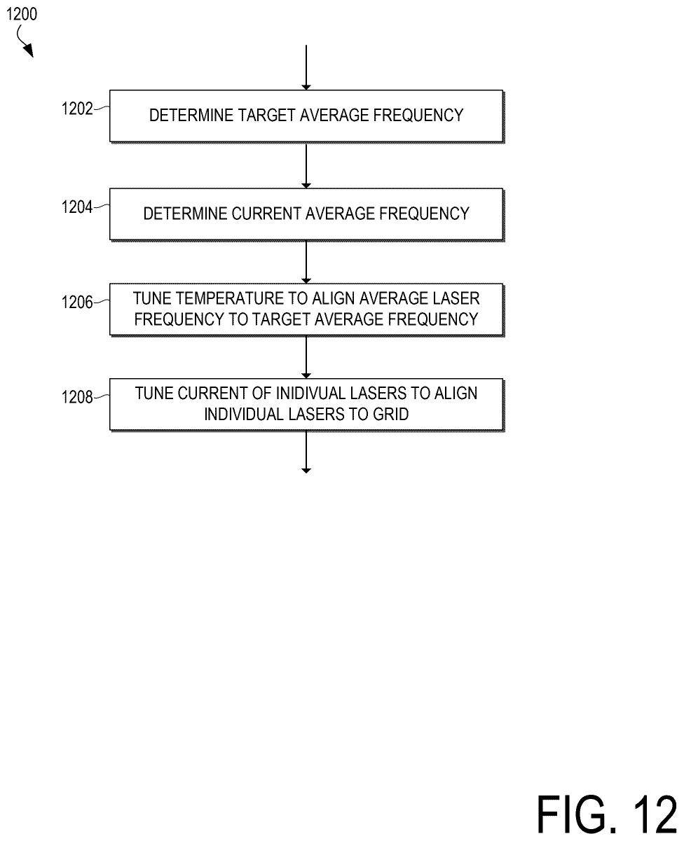

Referring now to FIG. 12, in one embodiment, the system 1100 may execute a method 1200 for controlling the lasers 104. The system 1100 may execute the method using any suitable combination of, e.g., hardware, software, firmware, modules, circuitry, and/or the like. For example, the system 1100 may include various modules, logic, and other components that may form a portion of, or otherwise be established by, a processor, memory, data storage, or other hardware components of the system. As such, in some embodiments, one or more of the modules of the system 100, such as the control circuitry 1106, may be embodied as circuitry or collection of electrical devices. Such circuitry may perform some or all of the method 1200.

The method 1200 begins in block 1202, in which the system 1100 determines a target average frequency for an array of lasers 104. In an illustrative embodiment, the target average frequency is the average channel frequency 206, as shown in FIG. 2. The system 1100, e.g., access a parameter for a protocol, access a saved value, etc., in order to determine the target average frequency.

In block 1204, the system 1100 determines the current average frequency of the lasers 104, such as the average frequency 208 shown in FIG. 2. To do so, the system 1100 may, e.g., measure the frequency of each of the lasers 104 in the array, determine an estimated frequency based on previous measurements of the frequency as a function of a temperature and driving current of the lasers 104, etc.

In block 1206, the system 1100 controls the temperature control device 106 to tune the temperature of the lasers 104 to align the average frequency 208 of the lasers 104 to the average frequency 206 of the channels, as shown in FIG. 3. For example, the system 1100 may implement a control loop, such as a PID control loop, based on closed-loop measurements of the average frequency 208 of the lasers 104. Additionally or alternatively, the system 100 may use another approach, such as open loop control.

In block 1208, the system 1100 tunes the current of individual lasers 104 of the array to align the individual lasers 104 to the corresponding grid frequency, as shown in FIG. 4.

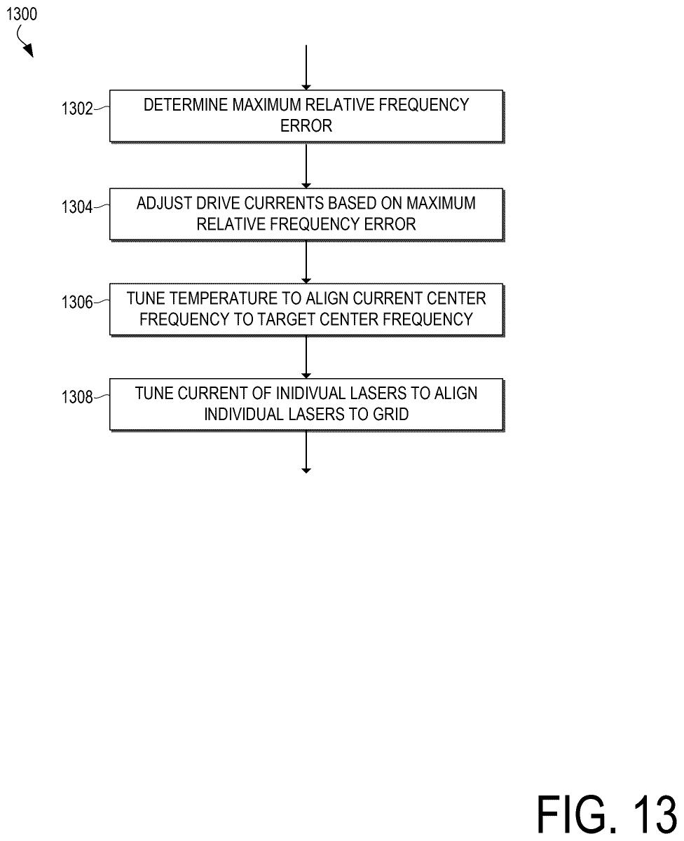

Referring now to FIG. 13, in one embodiment, the system 1100 may execute a method 1300 for controlling the lasers 104. The system 1100 may execute the method using any suitable combination of, e.g., hardware, software, firmware, modules, circuitry, and/or the like. For example, the system 1100 may include various modules, logic, and other components that may form a portion of, or otherwise be established by, a processor, memory, data storage, or other hardware components of the system. As such, in some embodiments, one or more of the modules of the system 100, such as the control circuitry 1106, may be embodied as circuitry or collection of electrical devices. Such circuitry may perform some or all of the method 1300.

For the method 1300, the system 1100 may align the array of lasers 104 to a prescribed fixed grid with a prescribed center frequency, using knowledge of relative frequency error for each laser. In block 1302, the system 1100 determines the maximum relative frequency error. To do so, in an illustrative embodiment, the system 1100 determines the relative frequency error for each lasers 104 and determines which relative frequency error is the highest.

In block 1304, the system 1100 adjusts the drive current of each of the lasers 104 based on the maximum relative frequency error in order to allow for maximum optical power (or minimum optical power) within a prescribed laser drive current range.

In block 1306, at the new drive currents, the system 1100 modifies the device temperature, e.g., with a backside temperature control device 106, such that the center frequency of the lasers 104 coincides with the prescribed center frequency.

In block 1308, the system 1100 tunes the drive currents for individual lasers 104 to align with an ideal grid around the average frequency of the grid, up to some accuracy and accounting for any crosstalk, including thermal crosstalk.

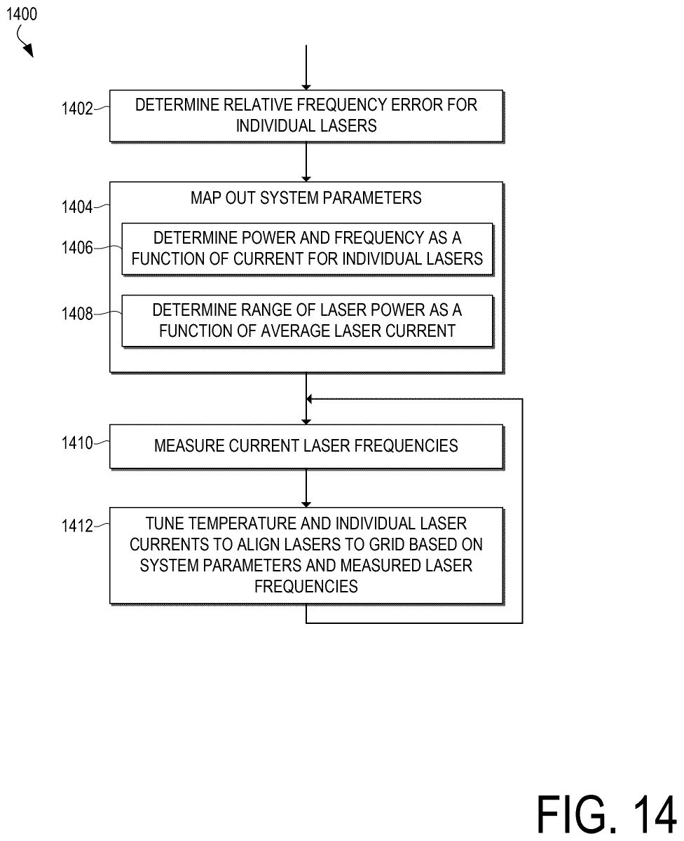

Referring now to FIG. 14, in one embodiment, the system 1100 may execute a method 1400 for controlling the lasers 104. The system 1100 may execute the method using any suitable combination of, e.g., hardware, software, firmware, modules, circuitry, and/or the like. For example, the system 1100 may include various modules, logic, and other components that may form a portion of, or otherwise be established by, a processor, memory, data storage, or other hardware components of the system. As such, in some embodiments, one or more of the modules of the system 100, such as the control circuitry 1106, may be embodied as circuitry or collection of electrical devices. Such circuitry may perform some or all of the method 1400.

For the method 1400, the system 1100 tune the array of lasers 104 to a prescribed grid with a prescribed center frequency, using knowledge of relative frequency error of individual lasers 104, as well knowledge of power vs. drive current for individual lasers 104, while maximizing the minimum power of any laser 104 in the array and/or minimizing the maximum power of any laser in the array.

In block 1402, the system 1100 determines the relative frequency error for each laser 104. In block 1404, the system 1100 maps out the parameters of the system 1100, such as during initialization and/or during a calibration process. For example, in block 1406 the system 1100 may determine the power and frequency as a function of various parameters, such as the temperature, the thermal power of the temperature control device 106, the drive current of the laser 104, the drive current of other lasers 104 in the array, etc. To do so, in an illustrative embodiment, the system 1100 Additionally or alternatively, the system 1100 may access one or more saved parameters, which may indicate some or all of the parameters to be determined. IN block 1408, the system 1100 may determine the range of power for all the lasers 104 in the array as a function of the average laser current.

In block 1410, the system 1100 measures the current frequencies of each of the lasers 104. In block 1412, the system 1100 tunes the temperature controlled by the temperature control device 106 and the driving current for individual lasers 104 of the laser array in order to align the lasers 104 to a grid based on the mapped-out system parameters and the measured frequencies of the lasers 104. For example, if a frequency of a laser 104 is too low, the system 1100 may reduce the drive current for that laser 104, which increases the frequency. In another example, the system 1100 may tune the temperature of the temperature control device 106, and tune the drive currents for each of the lasers 104 to compensate. The system 1100 may, e.g., control the temperature of the temperature control device 106 based on a maximum or minimum power of a laser 104 in the array. For example, the system 1100 may control the temperature of the temperature control device 106 to keep the maximum (or minimum) current of a laser 104 in the array near the maximum current 506 (or minimum current 504). The system 1100 may then control the drive current of each of the lasers 104 to keep the lasers 104 on the corresponding channel frequency.

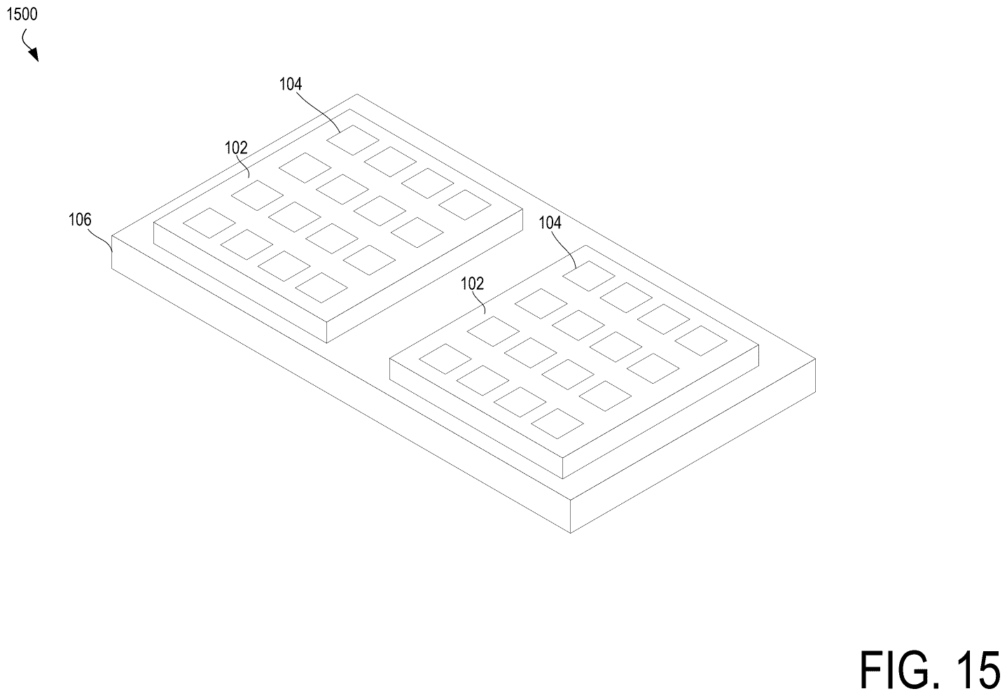

It should be appreciated that the approaches described herein may be employed in different configurations besides those explicitly described above. For example, in some embodiments, a system 1500 may include a temperature control device 106, such as a thermoelectric cooler, with two or more dies 102, each of which may include an array of lasers 104, as shown in FIG. 15. In some embodiments, the lasers 104 on two different dies 102 may be part of the same laser array for a communication protocol (i.e., may form a set of evenly-spaced channels). In other embodiments, the lasers 104 may be part of independent communication channels, such as by being coupled to separate optical fibers. It should be appreciated that, in the illustrative embodiment, the temperature control device 106 controls an average temperature for both of the dies 102 and the lasers 104 on the dies. Additionally or alternatively, in some embodiments, a system 1500 may include two or more temperature control devices 106, each of which may be thermally coupled to two or more dies 102 with lasers 104. In the illustrative embodiments, the fine-tuning for the frequency of each laser 104 is achieved by tuning the laser current. Additionally or alternatively, in some embodiments, the lasers 104 can be fine-tuned by using a local heater near each laser 104 to tune the temperature (and therefore frequency) for each laser 104.

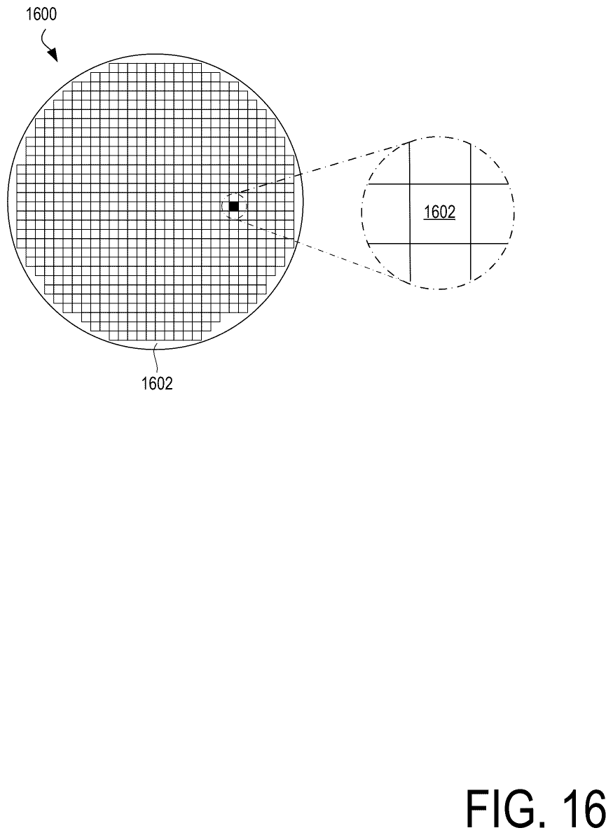

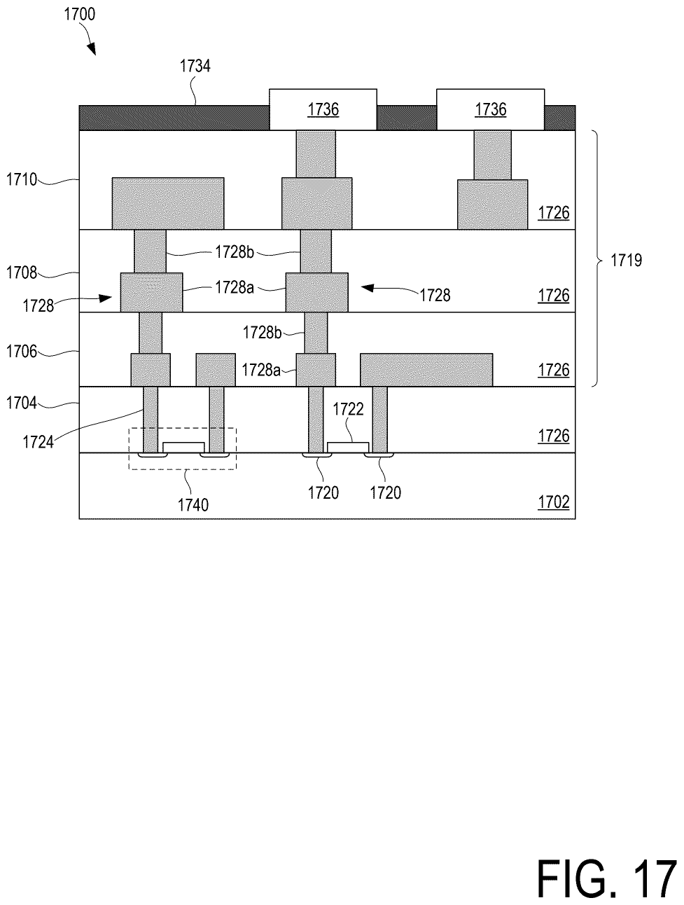

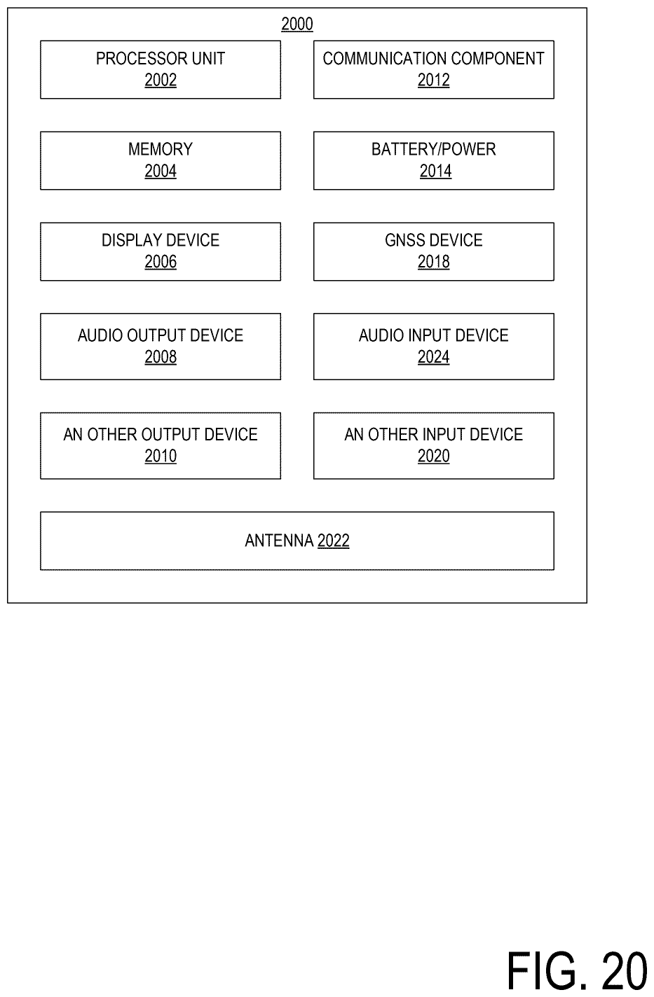

FIG. 16 is a top view of a wafer 1600 and dies 1602 that may be included in any of the systems 100 disclosed herein (e.g., as any suitable ones of the dies 102). The wafer 1600 may be composed of semiconductor material and may include one or more dies 1602 having integrated circuit structures formed on a surface of the wafer 1600. The individual dies 1602 may be a repeating unit of an integrated circuit product that includes any suitable integrated circuit. After the fabrication of the semiconductor product is complete, the wafer 1600 may undergo a singulation process in which the dies 1602 are separated from one another to provide discrete “chips” of the integrated circuit product. The die 1602 may be any of the dies 102 disclosed herein. The die 1602 may include one or more transistors (e.g., some of the transistors 1740 of FIG. 17, discussed below), supporting circuitry to route electrical signals to the transistors, passive components (e.g., signal traces, resistors, capacitors, or inductors), and/or any other integrated circuit components. In some embodiments, the wafer 1600 or the die 1602 may include a memory device (e.g., a random access memory (RAM) device, such as a static RAM (SRAM) device, a magnetic RAM (MRAM) device, a resistive RAM (RRAM) device, a conductive-bridging RAM (CBRAM) device, etc.), a logic device (e.g., an AND, OR, NAND, or NOR gate), or any other suitable circuit element. Multiple ones of these devices may be combined on a single die 1602. For example, a memory array formed by multiple memory devices may be formed on a same die 1602 as a processor unit (e.g., the processor unit 2002 of FIG. 20) or other logic that is configured to store information in the memory devices or execute instructions stored in the memory array. Various ones of the systems 100 disclosed herein may be manufactured using a die-to-wafer assembly technique in which some dies 102 are attached to a wafer 1600 that include others of the dies 102, and the wafer 1600 is subsequently singulated.

FIG. 17 is a cross-sectional side view of an integrated circuit device 1700 that may be included in any of the systems 100 disclosed herein (e.g., as any of the dies 102 or as a component with one or more electronic integrated circuits mated to the dies 102). One or more of the integrated circuit devices 1700 may be included in one or more dies 1602 (FIG. 16). The integrated circuit device 1700 may be formed on a die substrate 1702 (e.g., the wafer 1600 of FIG. 16) and may be included in a die (e.g., the die 1602 of FIG. 16). The die substrate 1702 may be a semiconductor substrate composed of semiconductor material systems including, for example, n-type or p-type materials systems (or a combination of both). The die substrate 1702 may include, for example, a crystalline substrate formed using a bulk silicon or a silicon-on-insulator (SOI) substructure. In some embodiments, the die substrate 1702 may be formed using alternative materials, which may or may not be combined with silicon, that include, but are not limited to, germanium, indium antimonide, lead telluride, indium arsenide, indium phosphide, gallium arsenide, or gallium antimonide. Further materials classified as group II-VI, III-V, or IV may also be used to form the die substrate 1702. Although a few examples of materials from which the die substrate 1702 may be formed are described here, any material that may serve as a foundation for an integrated circuit device 1700 may be used. The die substrate 1702 may be part of a singulated die (e.g., the dies 1602 of FIG. 16) or a wafer (e.g., the wafer 1600 of FIG. 16).

The integrated circuit device 1700 may include one or more device layers 1704 disposed on the die substrate 1702. The device layer 1704 may include features of one or more transistors 1740 (e.g., metal oxide semiconductor field-effect transistors (MOSFETs)) formed on the die substrate 1702. The transistors 1740 may include, for example, one or more source and/or drain (S/D) regions 1720, a gate 1722 to control current flow between the S/D regions 1720, and one or more S/D contacts 1724 to route electrical signals to/from the S/D regions 1720. The transistors 1740 may include additional features not depicted for the sake of clarity, such as device isolation regions, gate contacts, and the like. The transistors 1740 are not limited to the type and configuration depicted in FIG. 17 and may include a wide variety of other types and configurations such as, for example, planar transistors, non-planar transistors, or a combination of both. Non-planar transistors may include FinFET transistors, such as double-gate transistors or tri-gate transistors, and wrap-around or all-around gate transistors, such as nanoribbon, nanosheet, or nanowire transistors.

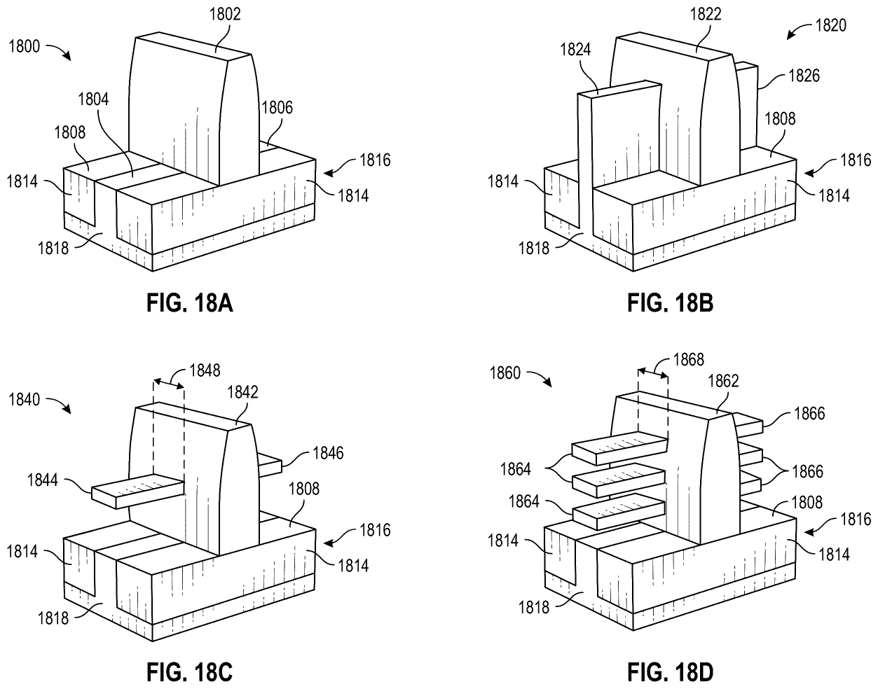

FIGS. 18A-18D are simplified perspective views of example planar, FinFET, gate-all-around, and stacked gate-all-around transistors. The transistors illustrated in FIGS. 18A-18D are formed on a substrate 1816 having a surface 1808. Isolation regions 1814 separate the source and drain regions of the transistors from other transistors and from a bulk region 1818 of the substrate 1816.

FIG. 18A is a perspective view of an example planar transistor 1800 comprising a gate 1802 that controls current flow between a source region 1804 and a drain region 1806. The transistor 1800 is planar in that the source region 1804 and the drain region 1806 are planar with respect to the substrate surface 1808.

FIG. 18B is a perspective view of an example FinFET transistor 1820 comprising a gate 1822 that controls current flow between a source region 1824 and a drain region 1826. The transistor 1820 is non-planar in that the source region 1824 and the drain region 1826 comprise “fins” that extend upwards from the substrate surface 1828. As the gate 1822 encompasses three sides of the semiconductor fin that extends from the source region 1824 to the drain region 1826, the transistor 1820 can be considered a tri-gate transistor. FIG. 18B illustrates one S/D fin extending through the gate 1822, but multiple S/D fins can extend through the gate of a FinFET transistor.

FIG. 18C is a perspective view of a gate-all-around (GAA) transistor 1840 comprising a gate 1842 that controls current flow between a source region 1844 and a drain region 1846. The transistor 1840 is non-planar in that the source region 1844 and the drain region 1846 are elevated from the substrate surface 1828.

FIG. 18D is a perspective view of a GAA transistor 1860 comprising a gate 1862 that controls current flow between multiple elevated source regions 1864 and multiple elevated drain regions 1866. The transistor 1860 is a stacked GAA transistor as the gate controls the flow of current between multiple elevated S/D regions stacked on top of each other. The transistors 1840 and 1860 are considered gate-all-around transistors as the gates encompass all sides of the semiconductor portions that extends from the source regions to the drain regions. The transistors 1840 and 1860 can alternatively be referred to as nanowire, nanosheet, or nanoribbon transistors depending on the width (e.g., widths 1848 and 1868 of transistors 1840 and 1860, respectively) of the semiconductor portions extending through the gate.

Returning to FIG. 17, a transistor 1740 may include a gate 1722 formed of at least two layers, a gate dielectric and a gate electrode. The gate dielectric may include one layer or a stack of layers. The one or more layers may include silicon oxide, silicon dioxide, silicon carbide, and/or a high-k dielectric material.

The high-k dielectric material may include elements such as hafnium, silicon, oxygen, titanium, tantalum, lanthanum, aluminum, zirconium, barium, strontium, yttrium, lead, scandium, niobium, and zinc. Examples of high-k materials that may be used in the gate dielectric include, but are not limited to, hafnium oxide, hafnium silicon oxide, lanthanum oxide, lanthanum aluminum oxide, zirconium oxide, zirconium silicon oxide, tantalum oxide, titanium oxide, barium strontium titanium oxide, barium titanium oxide, strontium titanium oxide, yttrium oxide, aluminum oxide, lead scandium tantalum oxide, and lead zinc niobate. In some embodiments, an annealing process may be carried out on the gate dielectric to improve its quality when a high-k material is used.

The gate electrode may be formed on the gate dielectric and may include at least one p-type work function metal or n-type work function metal, depending on whether the transistor 1740 is to be a p-type metal oxide semiconductor (PMOS) or an n-type metal oxide semiconductor (NMOS) transistor. In some implementations, the gate electrode may consist of a stack of two or more metal layers, where one or more metal layers are work function metal layers and at least one metal layer is a fill metal layer. Further metal layers may be included for other purposes, such as a barrier layer.

For a PMOS transistor, metals that may be used for the gate electrode include, but are not limited to, ruthenium, palladium, platinum, cobalt, nickel, conductive metal oxides (e.g., ruthenium oxide), and any of the metals discussed below with reference to an NMOS transistor (e.g., for work function tuning). For an NMOS transistor, metals that may be used for the gate electrode include, but are not limited to, hafnium, zirconium, titanium, tantalum, aluminum, alloys of these metals, carbides of these metals (e.g., hafnium carbide, zirconium carbide, titanium carbide, tantalum carbide, and aluminum carbide), and any of the metals discussed above with reference to a PMOS transistor (e.g., for work function tuning).

In some embodiments, when viewed as a cross-section of the transistor 1740 along the source-channel-drain direction, the gate electrode may consist of a U-shaped structure that includes a bottom portion substantially parallel to the surface of the die substrate 1702 and two sidewall portions that are substantially perpendicular to the top surface of the die substrate 1702. In other embodiments, at least one of the metal layers that form the gate electrode may simply be a planar layer that is substantially parallel to the top surface of the die substrate 1702 and does not include sidewall portions substantially perpendicular to the top surface of the die substrate 1702. In other embodiments, the gate electrode may consist of a combination of U-shaped structures and planar, non-U-shaped structures. For example, the gate electrode may consist of one or more U-shaped metal layers formed atop one or more planar, non-U-shaped layers.

In some embodiments, a pair of sidewall spacers may be formed on opposing sides of the gate stack to bracket the gate stack. The sidewall spacers may be formed from materials such as silicon nitride, silicon oxide, silicon carbide, silicon nitride doped with carbon, and silicon oxynitride. Processes for forming sidewall spacers are well known in the art and generally include deposition and etching process steps. In some embodiments, a plurality of spacer pairs may be used; for instance, two pairs, three pairs, or four pairs of sidewall spacers may be formed on opposing sides of the gate stack.

The S/D regions 1720 may be formed within the die substrate 1702 adjacent to the gate 1722 of individual transistors 1740. The S/D regions 1720 may be formed using an implantation/diffusion process or an etching/deposition process, for example. In the former process, dopants such as boron, aluminum, antimony, phosphorous, or arsenic may be ion-implanted into the die substrate 1702 to form the S/D regions 1720. An annealing process that activates the dopants and causes them to diffuse farther into the die substrate 1702 may follow the ion-implantation process. In the latter process, the die substrate 1702 may first be etched to form recesses at the locations of the S/D regions 1720. An epitaxial deposition process may then be carried out to fill the recesses with material that is used to fabricate the S/D regions 1720. In some implementations, the S/D regions 1720 may be fabricated using a silicon alloy such as silicon germanium or silicon carbide. In some embodiments, the epitaxially deposited silicon alloy may be doped in situ with dopants such as boron, arsenic, or phosphorous. In some embodiments, the S/D regions 1720 may be formed using one or more alternate semiconductor materials such as germanium or a group III-V material or alloy. In further embodiments, one or more layers of metal and/or metal alloys may be used to form the S/D regions 1720.

Electrical signals, such as power and/or input/output (I/O) signals, may be routed to and/or from the devices (e.g., transistors 1740) of the device layer 1704 through one or more interconnect layers disposed on the device layer 1704 (illustrated in FIG. 17 as interconnect layers 1706-1710). For example, electrically conductive features of the device layer 1704 (e.g., the gate 1722 and the S/D contacts 1724) may be electrically coupled with the interconnect structures 1728 of the interconnect layers 1706-1710. The one or more interconnect layers 1706-1710 may form a metallization stack (also referred to as an “ILD stack”) 1719 of the integrated circuit device 1700.

The interconnect structures 1728 may be arranged within the interconnect layers 1706-1710 to route electrical signals according to a wide variety of designs; in particular, the arrangement is not limited to the particular configuration of interconnect structures 1728 depicted in FIG. 17. Although a particular number of interconnect layers 1706-1710 is depicted in FIG. 17, embodiments of the present disclosure include integrated circuit devices having more or fewer interconnect layers than depicted.

In some embodiments, the interconnect structures 1728 may include lines 1728a and/or vias 1728b filled with an electrically conductive material such as a metal. The lines 1728a may be arranged to route electrical signals in a direction of a plane that is substantially parallel with a surface of the die substrate 1702 upon which the device layer 1704 is formed. For example, the lines 1728a may route electrical signals in a direction in and out of the page and/or in a direction across the page. The vias 1728b may be arranged to route electrical signals in a direction of a plane that is substantially perpendicular to the surface of the die substrate 1702 upon which the device layer 1704 is formed. In some embodiments, the vias 1728b may electrically couple lines 1728a of different interconnect layers 1706-1710 together.

The interconnect layers 1706-1710 may include a dielectric material 1726 disposed between the interconnect structures 1728, as shown in FIG. 17. In some embodiments, dielectric material 1726 disposed between the interconnect structures 1728 in different ones of the interconnect layers 1706-1710 may have different compositions; in other embodiments, the composition of the dielectric material 1726 between different interconnect layers 1706-1710 may be the same. The device layer 1704 may include a dielectric material 1726 disposed between the transistors 1740 and a bottom layer of the metallization stack as well. The dielectric material 1726 included in the device layer 1704 may have a different composition than the dielectric material 1726 included in the interconnect layers 1706-1710; in other embodiments, the composition of the dielectric material 1726 in the device layer 1704 may be the same as a dielectric material 1726 included in any one of the interconnect layers 1706-1710.

A first interconnect layer 1706 (referred to as Metal 1 or “M1”) may be formed directly on the device layer 1704. In some embodiments, the first interconnect layer 1706 may include lines 1728a and/or vias 1728b, as shown. The lines 1728a of the first interconnect layer 1706 may be coupled with contacts (e.g., the S/D contacts 1724) of the device layer 1704. The vias 1728b of the first interconnect layer 1706 may be coupled with the lines 1728a of a second interconnect layer 1708.

The second interconnect layer 1708 (referred to as Metal 2 or “M2”) may be formed directly on the first interconnect layer 1706. In some embodiments, the second interconnect layer 1708 may include via 1728b to couple the lines 1728 of the second interconnect layer 1708 with the lines 1728a of a third interconnect layer 1710. Although the lines 1728a and the vias 1728b are structurally delineated with a line within individual interconnect layers for the sake of clarity, the lines 1728a and the vias 1728b may be structurally and/or materially contiguous (e.g., simultaneously filled during a dual-damascene process) in some embodiments.

The third interconnect layer 1710 (referred to as Metal 3 or “M3”) (and additional interconnect layers, as desired) may be formed in succession on the second interconnect layer 1708 according to similar techniques and configurations described in connection with the second interconnect layer 1708 or the first interconnect layer 1706. In some embodiments, the interconnect layers that are “higher up” in the metallization stack 1719 in the integrated circuit device 1700 (i.e., farther away from the device layer 1704) may be thicker that the interconnect layers that are lower in the metallization stack 1719, with lines 1728a and vias 1728b in the higher interconnect layers being thicker than those in the lower interconnect layers.

The integrated circuit device 1700 may include a solder resist material 1734 (e.g., polyimide or similar material) and one or more conductive contacts 1736 formed on the interconnect layers 1706-1710. In FIG. 17, the conductive contacts 1736 are illustrated as taking the form of bond pads. The conductive contacts 1736 may be electrically coupled with the interconnect structures 1728 and configured to route the electrical signals of the transistor(s) 1740 to external devices. For example, solder bonds may be formed on the one or more conductive contacts 1736 to mechanically and/or electrically couple an integrated circuit die including the integrated circuit device 1700 with another component (e.g., a printed circuit board). The integrated circuit device 1700 may include additional or alternate structures to route the electrical signals from the interconnect layers 1706-1710; for example, the conductive contacts 1736 may include other analogous features (e.g., posts) that route the electrical signals to external components.

In some embodiments in which the integrated circuit device 1700 is a double-sided die, the integrated circuit device 1700 may include another metallization stack (not shown) on the opposite side of the device layer(s) 1704. This metallization stack may include multiple interconnect layers as discussed above with reference to the interconnect layers 1706-1710, to provide conductive pathways (e.g., including conductive lines and vias) between the device layer(s) 1704 and additional conductive contacts (not shown) on the opposite side of the integrated circuit device 1700 from the conductive contacts 1736.

In other embodiments in which the integrated circuit device 1700 is a double-sided die, the integrated circuit device 1700 may include one or more through silicon vias (TSVs) through the die substrate 1702; these TSVs may make contact with the device layer(s) 1704, and may provide conductive pathways between the device layer(s) 1704 and additional conductive contacts (not shown) on the opposite side of the integrated circuit device 1700 from the conductive contacts 1736. In some embodiments, TSVs extending through the substrate can be used for routing power and ground signals from conductive contacts on the opposite side of the integrated circuit device 1700 from the conductive contacts 1736 to the transistors 1740 and any other components integrated into the die, and the metallization stack 1719 can be used to route I/O signals from the conductive contacts 1736 to transistors 1740 and any other components integrated into the die.

Multiple integrated circuit devices 1700 may be stacked with one or more TSVs in the individual stacked devices providing connection between one of the devices to any of the other devices in the stack. For example, one or more high-bandwidth memory (HBM) integrated circuit dies can be stacked on top of a base integrated circuit die and TSVs in the HBM dies can provide connection between the individual HBM and the base integrated circuit die. Conductive contacts can provide additional connections between adjacent integrated circuit dies in the stack. In some embodiments, the conductive contacts can be fine-pitch solder bumps (microbumps).

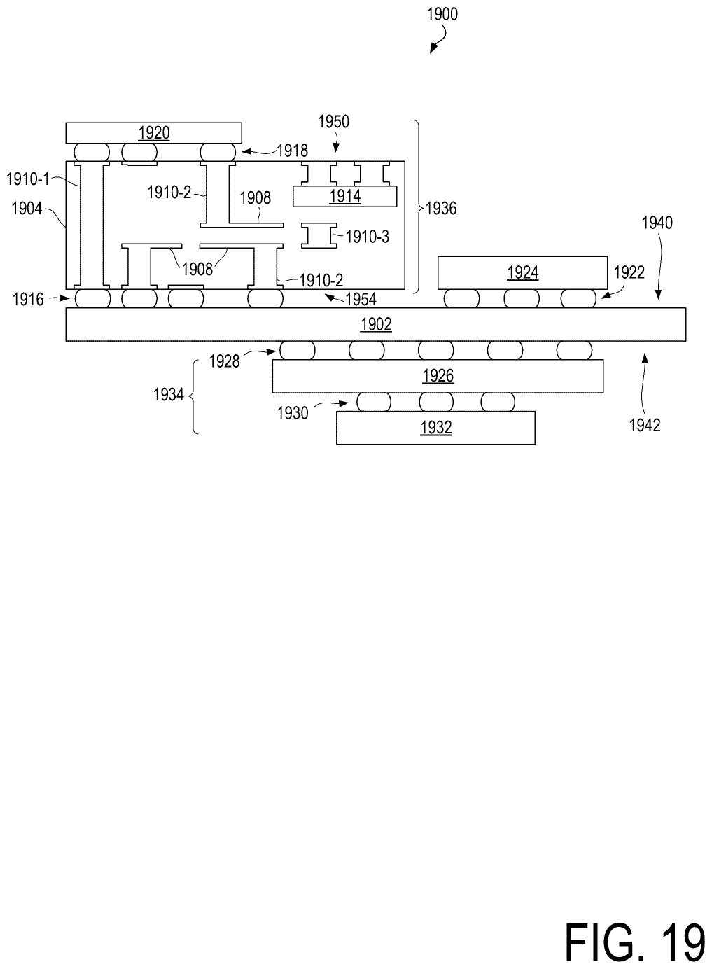

FIG. 19 is a cross-sectional side view of an integrated circuit device assembly 1900 that may include any of the systems 100 disclosed herein. In some embodiments, the integrated circuit device assembly 1900 may be a system 100. The integrated circuit device assembly 1900 includes a number of components disposed on a circuit board 1902 (which may be a motherboard, system board, mainboard, etc.). The integrated circuit device assembly 1900 includes components disposed on a first face 1940 of the circuit board 1902 and an opposing second face 1942 of the circuit board 1902; generally, components may be disposed on one or both faces 1940 and 1942. Any of the integrated circuit components discussed below with reference to the integrated circuit device assembly 1900 may take the form of any suitable ones of the embodiments of the systems 100 disclosed herein.

In some embodiments, the circuit board 1902 may be a printed circuit board (PCB) including multiple metal (or interconnect) layers separated from one another by layers of dielectric material and interconnected by electrically conductive vias. The individual metal layers comprise conductive traces. Any one or more of the metal layers may be formed in a desired circuit pattern to route electrical signals (optionally in conjunction with other metal layers) between the components coupled to the circuit board 1902. In other embodiments, the circuit board 1902 may be a non-PCB substrate. The integrated circuit device assembly 1900 illustrated in FIG. 19 includes a package-on-interposer structure 1936 coupled to the first face 1940 of the circuit board 1902 by coupling components 1916. The coupling components 1916 may electrically and mechanically couple the package-on-interposer structure 1936 to the circuit board 1902, and may include solder balls (as shown in FIG. 19), pins (e.g., as part of a pin grid array (PGA), contacts (e.g., as part of a land grid array (LGA)), male and female portions of a socket, an adhesive, an underfill material, and/or any other suitable electrical and/or mechanical coupling structure.

The package-on-interposer structure 1936 may include an integrated circuit component 1920 coupled to an interposer 1904 by coupling components 1918. The coupling components 1918 may take any suitable form for the application, such as the forms discussed above with reference to the coupling components 1916. Although a single integrated circuit component 1920 is shown in FIG. 19, multiple integrated circuit components may be coupled to the interposer 1904; indeed, additional interposers may be coupled to the interposer 1904. The interposer 1904 may provide an intervening substrate used to bridge the circuit board 1902 and the integrated circuit component 1920.

The integrated circuit component 1920 may be a packaged or unpacked integrated circuit product that includes one or more integrated circuit dies (e.g., the die 1602 of FIG. 16, the integrated circuit device 1700 of FIG. 17) and/or one or more other suitable components. A packaged integrated circuit component comprises one or more integrated circuit dies mounted on a package substrate with the integrated circuit dies and package substrate encapsulated in a casing material, such as a metal, plastic, glass, or ceramic. In one example of an unpackaged integrated circuit component 1920, a single monolithic integrated circuit die comprises solder bumps attached to contacts on the die. The solder bumps allow the die to be directly attached to the interposer 1904. The integrated circuit component 1920 can comprise one or more computing system components, such as one or more processor units (e.g., system-on-a-chip (SoC), processor core, graphics processor unit (GPU), accelerator, chipset processor), I/O controller, memory, or network interface controller. In some embodiments, the integrated circuit component 1920 can comprise one or more additional active or passive devices such as capacitors, decoupling capacitors, resistors, inductors, fuses, diodes, transformers, sensors, electrostatic discharge (ESD) devices, and memory devices.

In embodiments where the integrated circuit component 1920 comprises multiple integrated circuit dies, they dies can be of the same type (a homogeneous multi-die integrated circuit component) or of two or more different types (a heterogeneous multi-die integrated circuit component). A multi-die integrated circuit component can be referred to as a multi-chip package (MCP) or multi-chip module (MCM).

In addition to comprising one or more processor units, the integrated circuit component 1920 can comprise additional components, such as embedded DRAM, stacked high bandwidth memory (HBM), shared cache memories, input/output (I/O) controllers, or memory controllers. Any of these additional components can be located on the same integrated circuit die as a processor unit, or on one or more integrated circuit dies separate from the integrated circuit dies comprising the processor units. These separate integrated circuit dies can be referred to as “chiplets”. In embodiments where an integrated circuit component comprises multiple integrated circuit dies, interconnections between dies can be provided by the package substrate, one or more silicon interposers, one or more silicon bridges embedded in the package substrate (such as Intel® embedded multi-die interconnect bridges (EMIBs)), or combinations thereof.

Generally, the interposer 1904 may spread connections to a wider pitch or reroute a connection to a different connection. For example, the interposer 1904 may couple the integrated circuit component 1920 to a set of ball grid array (BGA) conductive contacts of the coupling components 1916 for coupling to the circuit board 1902. In the embodiment illustrated in FIG. 19, the integrated circuit component 1920 and the circuit board 1902 are attached to opposing sides of the interposer 1904; in other embodiments, the integrated circuit component 1920 and the circuit board 1902 may be attached to a same side of the interposer 1904. In some embodiments, three or more components may be interconnected by way of the interposer 1904.

In some embodiments, the interposer 1904 may be formed as a PCB, including multiple metal layers separated from one another by layers of dielectric material and interconnected by electrically conductive vias. In some embodiments, the interposer 1904 may be formed of an epoxy resin, a fiberglass-reinforced epoxy resin, an epoxy resin with inorganic fillers, a ceramic material, or a polymer material such as polyimide. In some embodiments, the interposer 1904 may be formed of alternate rigid or flexible materials that may include the same materials described above for use in a semiconductor substrate, such as silicon, germanium, and other group III-V and group IV materials. The interposer 1904 may include metal interconnects 1908 and vias 1910, including but not limited to through hole vias 1910-1 (that extend from a first face 1950 of the interposer 1904 to a second face 1954 of the interposer 1904), blind vias 1910-2 (that extend from the first or second faces 1950 or 1954 of the interposer 1904 to an internal metal layer), and buried vias 1910-3 (that connect internal metal layers).

In some embodiments, the interposer 1904 can comprise a silicon interposer. Through silicon vias (TSV) extending through the silicon interposer can connect connections on a first face of a silicon interposer to an opposing second face of the silicon interposer. In some embodiments, an interposer 1904 comprising a silicon interposer can further comprise one or more routing layers to route connections on a first face of the interposer 1904 to an opposing second face of the interposer 1904.

The interposer 1904 may further include embedded devices 1914, including both passive and active devices. Such devices may include, but are not limited to, capacitors, decoupling capacitors, resistors, inductors, fuses, diodes, transformers, sensors, electrostatic discharge (ESD) devices, and memory devices. More complex devices such as radio frequency devices, power amplifiers, power management devices, antennas, arrays, sensors, and microelectromechanical systems (MEMS) devices may also be formed on the interposer 1904. The package-on-interposer structure 1936 may take the form of any of the package-on-interposer structures known in the art.

The integrated circuit device assembly 1900 may include an integrated circuit component 1924 coupled to the first face 1940 of the circuit board 1902 by coupling components 1922. The coupling components 1922 may take the form of any of the embodiments discussed above with reference to the coupling components 1916, and the integrated circuit component 1924 may take the form of any of the embodiments discussed above with reference to the integrated circuit component 1920.

The integrated circuit device assembly 1900 illustrated in FIG. 19 includes a package-on-package structure 1934 coupled to the second face 1942 of the circuit board 1902 by coupling components 1928. The package-on-package structure 1934 may include an integrated circuit component 1926 and an integrated circuit component 1932 coupled together by coupling components 1930 such that the integrated circuit component 1926 is disposed between the circuit board 1902 and the integrated circuit component 1932. The coupling components 1928 and 1930 may take the form of any of the embodiments of the coupling components 1916 discussed above, and the integrated circuit components 1926 and 1932 may take the form of any of the embodiments of the integrated circuit component 1920 discussed above. The package-on-package structure 1934 may be configured in accordance with any of the package-on-package structures known in the art.

FIG. 20 is a block diagram of an example electrical device 2000 that may include one or more of the systems 100 disclosed herein. For example, any suitable ones of the components of the electrical device 2000 may include one or more of the integrated circuit device assemblies 1900, integrated circuit components 1920, integrated circuit devices 1700, or integrated circuit dies 1602 disclosed herein, and may be arranged in any of the systems 100 disclosed herein. A number of components are illustrated in FIG. 20 as included in the electrical device 2000, but any one or more of these components may be omitted or duplicated, as suitable for the application. In some embodiments, some or all of the components included in the electrical device 2000 may be attached to one or more motherboards mainboards, or system boards. In some embodiments, one or more of these components are fabricated onto a single system-on-a-chip (SoC) die.

Additionally, in various embodiments, the electrical device 2000 may not include one or more of the components illustrated in FIG. 20, but the electrical device 2000 may include interface circuitry for coupling to the one or more components. For example, the electrical device 2000 may not include a display device 2006, but may include display device interface circuitry (e.g., a connector and driver circuitry) to which a display device 2006 may be coupled. In another set of examples, the electrical device 2000 may not include an audio input device 2024 or an audio output device 2008, but may include audio input or output device interface circuitry (e.g., connectors and supporting circuitry) to which an audio input device 2024 or audio output device 2008 may be coupled.

The electrical device 2000 may include one or more processor units 2002 (e.g., one or more processor units). As used herein, the terms “processor unit”, “processing unit” or “processor” may refer to any device or portion of a device that processes electronic data from registers and/or memory to transform that electronic data into other electronic data that may be stored in registers and/or memory. The processor unit 2002 may include one or more digital signal processors (DSPs), application-specific integrated circuits (ASICs), central processing units (CPUs), graphics processing units (GPUs), general-purpose GPUs (GPGPUs), accelerated processing units (APUs), field-programmable gate arrays (FPGAs), neural network processing units (NPUs), data processor units (DPUs), accelerators (e.g., graphics accelerator, compression accelerator, artificial intelligence accelerator), controller cryptoprocessors (specialized processors that execute cryptographic algorithms within hardware), server processors, controllers, or any other suitable type of processor units. As such, the processor unit can be referred to as an XPU (or xPU).

The electrical device 2000 may include a memory 2004, which may itself include one or more memory devices such as volatile memory (e.g., dynamic random access memory (DRAM), static random-access memory (SRAM)), non-volatile memory (e.g., read-only memory (ROM), flash memory, chalcogenide-based phase-change non-voltage memories), solid state memory, and/or a hard drive. In some embodiments, the memory 2004 may include memory that is located on the same integrated circuit die as the processor unit 2002. This memory may be used as cache memory (e.g., Level 1 (L1), Level 2 (L2), Level 3 (L3), Level 4 (L4), Last Level Cache (LLC)) and may include embedded dynamic random access memory (eDRAM) or spin transfer torque magnetic random access memory (STT-MRAM).

In some embodiments, the electrical device 2000 can comprise one or more processor units 2002 that are heterogeneous or asymmetric to another processor unit 2002 in the electrical device 2000. There can be a variety of differences between the processing units 2002 in a system in terms of a spectrum of metrics of merit including architectural, microarchitectural, thermal, power consumption characteristics, and the like. These differences can effectively manifest themselves as asymmetry and heterogeneity among the processor units 2002 in the electrical device 2000.

In some embodiments, the electrical device 2000 may include a communication component 2012 (e.g., one or more communication components). For example, the communication component 2012 can manage wireless communications for the transfer of data to and from the electrical device 2000. The term “wireless” and its derivatives may be used to describe circuits, devices, systems, methods, techniques, communications channels, etc., that may communicate data through the use of modulated electromagnetic radiation through a nonsolid medium. The term “wireless” does not imply that the associated devices do not contain any wires, although in some embodiments they might not.

The communication component 2012 may implement any of a number of wireless standards or protocols, including but not limited to Institute for Electrical and Electronic Engineers (IEEE) standards including Wi-Fi (IEEE 802.11 family), IEEE 802.16 standards (e.g., IEEE 802.16-2005 Amendment), Long-Term Evolution (LTE) project along with any amendments, updates, and/or revisions (e.g., advanced LTE project, ultra mobile broadband (UMB) project (also referred to as “3GPP2”), etc.). IEEE 802.16 compatible Broadband Wireless Access (BWA) networks are generally referred to as WiMAX networks, an acronym that stands for Worldwide Interoperability for Microwave Access, which is a certification mark for products that pass conformity and interoperability tests for the IEEE 802.16 standards. The communication component 2012 may operate in accordance with a Global System for Mobile Communication (GSM), General Packet Radio Service (GPRS), Universal Mobile Telecommunications System (UMTS), High Speed Packet Access (HSPA), Evolved HSPA (E-HSPA), or LTE network. The communication component 2012 may operate in accordance with Enhanced Data for GSM Evolution (EDGE), GSM EDGE Radio Access Network (GERAN), Universal Terrestrial Radio Access Network (UTRAN), or Evolved UTRAN (E-UTRAN). The communication component 2012 may operate in accordance with Code Division Multiple Access (CDMA), Time Division Multiple Access (TDMA), Digital Enhanced Cordless Telecommunications (DECT), Evolution-Data Optimized (EV-DO), and derivatives thereof, as well as any other wireless protocols that are designated as 3G, 4G, 5G, and beyond. The communication component 2012 may operate in accordance with other wireless protocols in other embodiments. The electrical device 2000 may include an antenna 2022 to facilitate wireless communications and/or to receive other wireless communications (such as AM or FM radio transmissions).

In some embodiments, the communication component 2012 may manage wired communications, such as electrical, optical, or any other suitable communication protocols (e.g., IEEE 802.3 Ethernet standards). As noted above, the communication component 2012 may include multiple communication components. For instance, a first communication component 2012 may be dedicated to shorter-range wireless communications such as Wi-Fi or Bluetooth, and a second communication component 2012 may be dedicated to longer-range wireless communications such as global positioning system (GPS), EDGE, GPRS, CDMA, WiMAX, LTE, EV-DO, or others. In some embodiments, a first communication component 2012 may be dedicated to wireless communications, and a second communication component 2012 may be dedicated to wired communications.

The electrical device 2000 may include battery/power circuitry 2014. The battery/power circuitry 2014 may include one or more energy storage devices (e.g., batteries or capacitors) and/or circuitry for coupling components of the electrical device 2000 to an energy source separate from the electrical device 2000 (e.g., AC line power).

The electrical device 2000 may include a display device 2006 (or corresponding interface circuitry, as discussed above). The display device 2006 may include one or more embedded or wired or wirelessly connected external visual indicators, such as a heads-up display, a computer monitor, a projector, a touchscreen display, a liquid crystal display (LCD), a light-emitting diode display, or a flat panel display.

The electrical device 2000 may include an audio output device 2008 (or corresponding interface circuitry, as discussed above). The audio output device 2008 may include any embedded or wired or wirelessly connected external device that generates an audible indicator, such as speakers, headsets, or earbuds.

The electrical device 2000 may include an audio input device 2024 (or corresponding interface circuitry, as discussed above). The audio input device 2024 may include any embedded or wired or wirelessly connected device that generates a signal representative of a sound, such as microphones, microphone arrays, or digital instruments (e.g., instruments having a musical instrument digital interface (MIDI) output). The electrical device 2000 may include a Global Navigation Satellite System (GNSS) device 2018 (or corresponding interface circuitry, as discussed above), such as a Global Positioning System (GPS) device. The GNSS device 2018 may be in communication with a satellite-based system and may determine a geolocation of the electrical device 2000 based on information received from one or more GNSS satellites, as known in the art.

The electrical device 2000 may include an other output device 2010 (or corresponding interface circuitry, as discussed above). Examples of the other output device 2010 may include an audio codec, a video codec, a printer, a wired or wireless transmitter for providing information to other devices, or an additional storage device.

The electrical device 2000 may include an other input device 2020 (or corresponding interface circuitry, as discussed above). Examples of the other input device 2020 may include an accelerometer, a gyroscope, a compass, an image capture device (e.g., monoscopic or stereoscopic camera), a trackball, a trackpad, a touchpad, a keyboard, a cursor control device such as a mouse, a stylus, a touchscreen, proximity sensor, microphone, a bar code reader, a Quick Response (QR) code reader, electrocardiogram (ECG) sensor, PPG (photoplethysmogram) sensor, galvanic skin response sensor, any other sensor, or a radio frequency identification (RFID) reader.

The electrical device 2000 may have any desired form factor, such as a hand-held or mobile electrical device (e.g., a cell phone, a smart phone, a mobile internet device, a music player, a tablet computer, a laptop computer, a 2-in-1 convertible computer, a portable all-in-one computer, a netbook computer, an ultrabook computer, a personal digital assistant (PDA), an ultra mobile personal computer, a portable gaming console, etc.), a desktop electrical device, a server, a rack-level computing solution (e.g., blade, tray or sled computing systems), a workstation or other networked computing component, a printer, a scanner, a monitor, a set-top box, an entertainment control unit, a stationary gaming console, smart television, a vehicle control unit, a digital camera, a digital video recorder, a wearable electrical device or an embedded computing system (e.g., computing systems that are part of a vehicle, smart home appliance, consumer electronics product or equipment, manufacturing equipment). In some embodiments, the electrical device 2000 may be any other electronic device that processes data. In some embodiments, the electrical device 2000 may comprise multiple discrete physical components. Given the range of devices that the electrical device 2000 can be manifested as in various embodiments, in some embodiments, the electrical device 2000 can be referred to as a computing device or a computing system.

### EXAMPLES

Illustrative examples of the technologies disclosed herein are provided below. An embodiment of the technologies may include any one or more, and any combination of, the examples described below.

Example 1 includes a system comprising one or more photonic integrated circuit (PIC) dies; a plurality of lasers, the plurality of lasers mounted on or integrated into the one or more PIC dies; a temperature control device that is thermally coupled to the one or more PIC dies; and control circuitry to control the temperature control device to control an amount of thermal power transferred between the one or more PIC dies and the temperature control device; and control, for individual lasers of the plurality of lasers, an amount of laser drive current for a corresponding laser of the plurality of lasers.

Example 2 includes the subject matter of Example 1, and wherein the control circuitry is to control the temperature control device and an amount of laser drive current for individual lasers of the plurality of lasers to align a frequency of individual lasers of the plurality of lasers to a corresponding channel frequency.

Example 3 includes the subject matter of any of Examples 1 and 2, and wherein to align a frequency of individual lasers of the plurality of lasers to a corresponding channel frequency comprises to align a frequency of individual lasers of the plurality of lasers to a corresponding channel frequency within less than 15 gigahertz.

Example 4 includes the subject matter of any of Examples 1-3, and wherein the control circuitry is to control the temperature control device to control an average frequency of the plurality of lasers; and control, for individual lasers of the plurality of lasers, an amount of laser drive current for the corresponding laser of the plurality of lasers to align a frequency of the corresponding laser to a corresponding channel frequency.

Example 5 includes the subject matter of any of Examples 1-4, and wherein the control circuitry is to control, for individual lasers of the plurality of lasers, an amount of laser drive current for the corresponding laser of the plurality of lasers to align a frequency of the corresponding laser to a corresponding channel frequency; and control the temperature control device at least partially based on a minimum or maximum laser drive current for the plurality of lasers.

Example 6 includes the subject matter of any of Examples 1-5, and wherein the control circuitry is to control the temperature control device at least partially based on a minimum laser drive current for the plurality of lasers.

Example 7 includes the subject matter of any of Examples 1-6, and wherein the control circuitry is to control the temperature control device at least partially based on a maximum laser drive current for the plurality of lasers.

Example 8 includes the subject matter of any of Examples 1-7, and wherein the control circuitry is to control the temperature control device to control an average frequency of the plurality of lasers at an initial laser drive current value; control, for individual lasers of the plurality of lasers, an amount of laser drive current for a corresponding laser of the plurality of lasers to align a frequency of the corresponding laser to a corresponding channel frequency; measure one or more parameters of the plurality of lasers as a function of an average laser driver current; and control the plurality of lasers based on the measured one or more parameters and a target operating condition.

Example 9 includes the subject matter of any of Examples 1-8, and wherein the plurality of lasers is to operate at a plurality of channel frequencies corresponding to a communication protocol.

Example 10 includes the subject matter of any of Examples 1-9, and wherein the plurality of channel frequencies are spaced apart by a fixed amount, wherein the fixed amount is between 10 and 500 gigahertz.

Example 11 includes the subject matter of any of Examples 1-10, and wherein to control the amount of thermal power transferred between the one or more PIC dies and the temperature control device comprises to shift an average frequency of the plurality of lasers by 1-300 gigahertz.

Example 12 includes the subject matter of any of Examples 1-11, and wherein to control, for individual lasers of the plurality of lasers, an amount of laser drive current for the corresponding laser of the plurality of lasers comprises to control, for individual lasers of the plurality of lasers, a frequency of the corresponding laser of the plurality of lasers by 1-300 gigahertz.

Example 13 includes the subject matter of any of Examples 1-12, and wherein individual lasers of the plurality of lasers comprise distributed feedback lasers.

Example 14 includes the subject matter of any of Examples 1-13, and wherein the temperature control device is a thermoelectric cooler.

Example 15 includes a system comprising one or more photonic integrated circuit (PIC) dies; a plurality of lasers, the plurality of lasers mounted on or integrated into the one or more PIC dies; a temperature control device that is thermally coupled to the one or more PIC dies; and control circuitry to control the temperature control device and a frequency for individual lasers of the plurality of lasers to align a frequency of individual lasers of the plurality of lasers to a corresponding channel frequency.

Example 16 includes the subject matter of Example 15, and wherein to align a frequency of individual lasers of the plurality of lasers to a corresponding channel frequency comprises to align a frequency of individual lasers of the plurality of lasers to a corresponding channel frequency within less than 15 gigahertz.

Example 17 includes the subject matter of any of Examples 15 and 16, and wherein the control circuitry is to control the temperature control device to control an average frequency of the plurality of lasers; and control, for individual lasers of the plurality of lasers, an amount of laser drive current for the corresponding laser of the plurality of lasers to align a frequency of the corresponding laser to a corresponding channel frequency.

Example 18 includes the subject matter of any of Examples 15-17, and wherein the control circuitry is to control, for individual lasers of the plurality of lasers, an amount of laser drive current for the corresponding laser of the plurality of lasers to align a frequency of the corresponding laser to a corresponding channel frequency; and control the temperature control device at least partially based on a minimum or maximum laser drive current for the plurality of lasers.

Example 19 includes the subject matter of any of Examples 15-18, and wherein the control circuitry is to control the temperature control device at least partially based on a minimum laser drive current for the plurality of lasers.

Example 20 includes the subject matter of any of Examples 15-19, and wherein the control circuitry is to control the temperature control device at least partially based on a maximum laser drive current for the plurality of lasers.

Example 21 includes the subject matter of any of Examples 15-20, and wherein the control circuitry is to control the temperature control device to control an average frequency of the plurality of lasers at an initial laser drive current value; control, for individual lasers of the plurality of lasers, an amount of laser drive current for the corresponding laser of the plurality of lasers to align a frequency of the corresponding laser to a corresponding channel frequency; measure one or more parameters of the plurality of lasers as a function of an average laser driver current; and control the plurality of lasers based on the measured one or more parameters and a target operating condition.

Example 22 includes the subject matter of any of Examples 15-21, and wherein the plurality of lasers are to operate at a plurality of channel frequencies corresponding to a communication protocol.

Example 23 includes the subject matter of any of Examples 15-22, and wherein the plurality of channel frequencies are spaced apart by a fixed amount, wherein the fixed amount is between 10 and 500 gigahertz.

Example 24 includes the subject matter of any of Examples 15-23, and wherein to control an amount of thermal power transferred between the one or more PIC dies and the temperature control device comprises to shift an average frequency of the plurality of lasers by 1-300 gigahertz.

Example 25 includes the subject matter of any of Examples 15-24, and wherein to control, for individual lasers of the plurality of lasers, a frequency for the corresponding laser of the plurality of lasers comprises to control, for individual lasers of the plurality of lasers, a frequency of the corresponding laser of the plurality of lasers by 1-300 gigahertz.

Example 26 includes the subject matter of any of Examples 15-25, and wherein individual lasers of the plurality of lasers comprise distributed feedback lasers.

Example 27 includes the subject matter of any of Examples 15-26, and wherein the temperature control device is a thermoelectric device.

Example 28 includes the subject matter of any of Examples 15-27, and wherein to control the frequency for individual lasers of the plurality of lasers comprises to control, for individual lasers of the plurality of lasers, a local heater to align a frequency of the corresponding laser to a corresponding channel frequency.

Example 29 includes one or more computer-readable media comprising a plurality of instructions stored thereon that, when executed by control circuitry of a compute device, causes the control circuitry to monitor a frequency of individual lasers of a plurality of lasers of the compute device, wherein the plurality of lasers is mounted on or integrated into a photonic integrated circuit (PIC) die of the compute device, wherein the PIC die is thermally coupled to a temperature control device of the compute device; control the temperature control device to control an amount of thermal power transferred between the one or more PIC dies and the temperature control device; and control, for individual lasers of the plurality of lasers, an amount of laser drive current for a corresponding laser of the plurality of lasers.

Example 30 includes the subject matter of Example 29, and wherein the plurality of instructions cause the control circuitry to control the temperature control device and an amount of laser drive current for individual lasers of the plurality of lasers to align a frequency of individual lasers of the plurality of lasers to a corresponding channel frequency.

Example 31 includes the subject matter of any of Examples 29 and 30, and wherein to align a frequency of individual lasers of the plurality of lasers to a corresponding channel frequency comprises to align a frequency of individual lasers of the plurality of lasers to a corresponding channel frequency within less than 15 gigahertz.

Example 32 includes the subject matter of any of Examples 29-31, and wherein the plurality of instructions cause the control circuitry to control the temperature control device to control an average frequency of the plurality of lasers; and control, for individual lasers of the plurality of lasers, an amount of laser drive current for the corresponding laser of the plurality of lasers to align a frequency of the corresponding laser to a corresponding channel frequency.

Example 33 includes the subject matter of any of Examples 29-32, and wherein the plurality of instructions cause the control circuitry to control, for individual lasers of the plurality of lasers, an amount of laser drive current for the corresponding laser of the plurality of lasers to align a frequency of the corresponding laser to a corresponding channel frequency; and control the temperature control device at least partially based on a minimum or maximum laser drive current for the plurality of lasers.

Example 34 includes the subject matter of any of Examples 29-33, and wherein the plurality of instructions cause the control circuitry to control the temperature control device at least partially based on a minimum laser drive current for the plurality of lasers.

Example 35 includes the subject matter of any of Examples 29-34, and wherein the plurality of instructions cause the control circuitry to control the temperature control device at least partially based on a maximum laser drive current for the plurality of lasers.

Example 36 includes the subject matter of any of Examples 29-35, and wherein the plurality of instructions cause the control circuitry to control the temperature control device to control an average frequency of the plurality of lasers at an initial laser drive current value; control, for individual lasers of the plurality of lasers, an amount of laser drive current for a corresponding laser of the plurality of lasers to align a frequency of the corresponding laser to a corresponding channel frequency; measure one or more parameters of the plurality of lasers as a function of an average laser driver current; and control the plurality of lasers based on the measured one or more parameters and a target operating condition.

Example 37 includes the subject matter of any of Examples 29-36, and wherein the plurality of instructions cause the plurality of lasers to operate at a plurality of channel frequencies corresponding to a communication protocol.

Example 38 includes the subject matter of any of Examples 29-37, and wherein the plurality of channel frequencies are spaced apart by a fixed amount, wherein the fixed amount is between 10 and 500 gigahertz.

Example 39 includes the subject matter of any of Examples 29-38, and wherein to control the amount of thermal power transferred between the one or more PIC dies and the temperature control device comprises to shift an average frequency of the plurality of lasers by 1-300 gigahertz.

Example 40 includes the subject matter of any of Examples 29-39, and wherein to control, for individual lasers of the plurality of lasers, an amount of laser drive current for the corresponding laser of the plurality of lasers comprises to control, for individual lasers of the plurality of lasers, a frequency of the corresponding laser of the plurality of lasers by 1-300 gigahertz.

Example 41 includes the subject matter of any of Examples 29-40, and wherein individual lasers of the plurality of lasers are distributed feedback lasers.

Example 42 includes the subject matter of any of Examples 29-41, and wherein the temperature control device is a thermoelectric cooler.

Example 43 includes a system comprising one or more photonic integrated circuit (PIC) dies comprising a plurality of lasers; means for changing a temperature of the plurality of lasers, wherein the means for controlling the temperature of the plurality of lasers is thermally coupled to the one or more PIC dies; means for controlling the means for changing the temperature of the plurality of lasers; and means for controlling an amount of laser drive current for individual lasers of the plurality of lasers.

Example 44 includes the subject matter of Example 43, and wherein means for controlling the means for changing the temperature of the plurality of lasers and the means for controlling an amount of laser drive current for individual lasers of the plurality of lasers are to align a frequency of individual lasers of the plurality of lasers to a corresponding channel frequency.

Example 45 includes the subject matter of any of Examples 43 and 44, and wherein to align a frequency of individual lasers of the plurality of lasers to a corresponding channel frequency comprises to align a frequency of individual lasers of the plurality of lasers to a corresponding channel frequency within less than 15 gigahertz.

Example 46 includes the subject matter of any of Examples 43-45, and wherein the means for controlling the means for changing the temperature of the plurality of lasers is to control an average frequency of the plurality of lasers, wherein the means for controlling an amount of laser drive current for individual lasers of the plurality of lasers comprises means for controlling an amount of laser drive current for individual lasers of the plurality of lasers to align a frequency of individual lasers of the plurality of lasers to a corresponding channel frequency.

Example 47 includes the subject matter of any of Examples 43-46, and wherein the means for controlling an amount of laser drive current for individual lasers of the plurality of lasers comprises means for controlling an amount of laser drive current for a corresponding laser of the plurality of lasers to align a frequency of the corresponding laser to a corresponding channel frequency, wherein the means for controlling the means for changing the temperature of the plurality of lasers comprises means for controlling the means for changing the temperature of the plurality of lasers at least partially based on a minimum or maximum laser drive current for the plurality of lasers.

Example 48 includes the subject matter of any of Examples 43-47, and wherein the means for controlling the means for changing the temperature of the plurality of lasers comprises means for controlling the means for changing the temperature of the plurality of lasers at least partially based on a minimum laser drive current for the plurality of lasers.

Example 49 includes the subject matter of any of Examples 43-48, and wherein the means for controlling the means for changing the temperature of the plurality of lasers comprises means for controlling the means for changing the temperature of the plurality of lasers at least partially based on a maximum laser drive current for the plurality of lasers.

Example 50 includes the subject matter of any of Examples 43-49, and wherein means for controlling the means for changing the temperature of the plurality of lasers comprises means for controlling the means for changing the temperature of the plurality of lasers to control an average frequency of the plurality of lasers at an initial laser drive current value, wherein the means for controlling an amount of laser drive current for individual lasers of the plurality of lasers comprises means for controlling an amount of laser drive current for individual lasers of the plurality of lasers to align a frequency of a corresponding laser to a corresponding channel frequency, means for measuring one or more parameters of the plurality of lasers as a function of an average laser driver current; and means for controlling the plurality of lasers based on the measured one or more parameters and a target operating condition.

Example 51 includes the subject matter of any of Examples 43-50, and wherein the plurality of lasers are to operate at a plurality of channel frequencies corresponding to a communication protocol.

Example 52 includes the subject matter of any of Examples 43-51, and wherein the plurality of channel frequencies are spaced apart by a fixed amount, wherein the fixed amount is between 10 and 500 gigahertz.

Example 53 includes the subject matter of any of Examples 43-52, and wherein means for controlling the means for changing the temperature of the plurality of lasers means for shifting an average frequency of the plurality of lasers by 1-300 gigahertz.

Example 54 includes the subject matter of any of Examples 43-53, and wherein the means for controlling an amount of laser drive current for individual lasers of the plurality of lasers comprises to control, for individual lasers of the plurality of lasers, a frequency of a corresponding laser of the plurality of lasers by 1-300 gigahertz.

Example 55 includes the subject matter of any of Examples 43-54, and wherein individual lasers of the plurality of lasers comprise distributed feedback lasers.

Example 56 includes the subject matter of any of Examples 43-55, and wherein the means for changing a temperature of the plurality of lasers is a thermoelectric device.

The invention claimed is:

1. A system comprising:
one or more photonic integrated circuit (PIC) dies;
a plurality of lasers, the plurality of lasers mounted on or integrated into the one or more PIC dies;
a temperature control device that is thermally coupled to the one or more PIC dies; and
control circuitry to:
control the temperature control device to control an amount of thermal power transferred between the one or more PIC dies and the temperature control device; and
control, for individual lasers of the plurality of lasers, an amount of laser drive current for a corresponding laser of the plurality of lasers.

2. The system of claim 1, wherein the control circuitry is to control the temperature control device and an amount of laser drive current for individual lasers of the plurality of lasers to align a frequency of individual lasers of the plurality of lasers to a corresponding channel frequency.

3. The system of claim 1, wherein to align a frequency of individual lasers of the plurality of lasers to a corresponding channel frequency comprises to align a frequency of individual lasers of the plurality of lasers to a corresponding channel frequency within less than 15 gigahertz.

4. The system of claim 1, wherein the control circuitry is to:
control the temperature control device to control an average frequency of the plurality of lasers; and
control, for individual lasers of the plurality of lasers, an amount of laser drive current for the corresponding laser of the plurality of lasers to align a frequency of the corresponding laser to a corresponding channel frequency.

5. The system of claim 1, wherein the control circuitry is to:
control, for individual lasers of the plurality of lasers, an amount of laser drive current for the corresponding laser of the plurality of lasers to align a frequency of the corresponding laser to a corresponding channel frequency; and
control the temperature control device at least partially based on a minimum or maximum laser drive current for the plurality of lasers.

6. The system of claim 1, wherein the control circuitry is to:
control the temperature control device to control an average frequency of the plurality of lasers at an initial laser drive current value;
control, for individual lasers of the plurality of lasers, an amount of laser drive current for a corresponding laser of the plurality of lasers to align a frequency of the corresponding laser to a corresponding channel frequency;
measure one or more parameters of the plurality of lasers as a function of an average laser driver current; and
control the plurality of lasers based on the measured one or more parameters and a target operating condition.

7. The system of claim 1, wherein the plurality of lasers is to operate at a plurality of channel frequencies corresponding to a communication protocol.

8. The system of claim 7, wherein the plurality of channel frequencies are spaced apart by a fixed amount, wherein the fixed amount is between 10 and 500 gigahertz.

9. The system of claim 1, wherein to control the amount of thermal power transferred between the one or more PIC dies and the temperature control device comprises to shift an average frequency of the plurality of lasers by 1-300 gigahertz.

10. The system of claim 1, wherein to control, for individual lasers of the plurality of lasers, an amount of laser drive current for the corresponding laser of the plurality of lasers comprises to control, for individual lasers of the plurality of lasers, a frequency of the corresponding laser of the plurality of lasers by 1-300 gigahertz.

11. The system of claim 1, wherein the temperature control device is a thermoelectric cooler.

12. A system comprising:
one or more photonic integrated circuit (PIC) dies;
a plurality of lasers, the plurality of lasers mounted on or integrated into the one or more PIC dies;
a temperature control device that is thermally coupled to the one or more PIC dies; and
control circuitry to control the temperature control device and a frequency for individual lasers of the plurality of lasers to align a frequency of individual lasers of the plurality of lasers to a corresponding channel frequency.

13. The system of claim 12, wherein to align a frequency of individual lasers of the plurality of lasers to a corresponding channel frequency comprises to align a frequency of individual lasers of the plurality of lasers to a corresponding channel frequency within less than 15 gigahertz.

14. The system of claim 12, wherein the control circuitry is to:
control the temperature control device to control an average frequency of the plurality of lasers; and
control, for individual lasers of the plurality of lasers, an amount of laser drive current for the corresponding laser of the plurality of lasers to align a frequency of the corresponding laser to a corresponding channel frequency.

15. The system of claim 12, wherein the control circuitry is to:
control, for individual lasers of the plurality of lasers, an amount of laser drive current for the corresponding laser of the plurality of lasers to align a frequency of the corresponding laser to a corresponding channel frequency; and
control the temperature control device at least partially based on a minimum or maximum laser drive current for the plurality of lasers.

16. The system of claim 12, wherein the control circuitry is to:
control the temperature control device to control an average frequency of the plurality of lasers at an initial laser drive current value;
control, for individual lasers of the plurality of lasers, an amount of laser drive current for the corresponding laser of the plurality of lasers to align a frequency of the corresponding laser to a corresponding channel frequency;
measure one or more parameters of the plurality of lasers as a function of an average laser driver current; and
control the plurality of lasers based on the measured one or more parameters and a target operating condition.

17. The system of claim 12, wherein to control the frequency for individual lasers of the plurality of lasers comprises to control, for individual lasers of the plurality of lasers, a local heater to align a frequency of the corresponding laser to a corresponding channel frequency.

18. One or more computer-readable media comprising a plurality of instructions stored thereon that, when executed by control circuitry of a compute device, causes the control circuitry to:
monitor a frequency of individual lasers of a plurality of lasers of the compute device, wherein the plurality of lasers is mounted on or integrated into a photonic integrated circuit (PIC) die of the compute device, wherein the PIC die is thermally coupled to a temperature control device of the compute device;
control the temperature control device to control an amount of thermal power transferred between the one or more PIC dies and the temperature control device; and
control, for individual lasers of the plurality of lasers, an amount of laser drive current for a corresponding laser of the plurality of lasers.

19. The one or more computer-readable media of claim 18, wherein the plurality of instructions cause the control circuitry to control the temperature control device and an amount of laser drive current for individual lasers of the plurality of lasers to align a frequency of individual lasers of the plurality of lasers to a corresponding channel frequency.

20. The one or more computer-readable media of claim 18, wherein the plurality of instructions cause the control circuitry to:
control the temperature control device to control an average frequency of the plurality of lasers; and
control, for individual lasers of the plurality of lasers, an amount of laser drive current for the corresponding laser of the plurality of lasers to align a frequency of the corresponding laser to a corresponding channel frequency.
